(19) United States
(12) Patent Application Publication
(10) Pub. No.: US 2021/0141308 A1
(43) Pub. Date: May 13, 2021

(54) RESIST COMPOSITION AND METHOD OF FORMING RESIST PATTERN

(71) Applicant: TOKYO OHKA KOGYO CO., LTD., Kawasaki-shi (JP)

(72) Inventors: Tsuyoshi Nakamura, Kawasaki-shi (JP); Jiro YOKOYA, Kawasaki-shi (JP); Hirokuni SAITO, Kawasaki-shi (JP)

(21) Appl. No.: 17/089,298

(22) Filed: Nov. 4, 2020

(30) Foreign Application Priority Data
Nov. 11, 2019 (JP) 2019-204241

(51) Int. Cl. G03F 7/039; G03F 7/20; G03F 7/32; C08F 220/28

(52) U.S. Cl. CPC G03F 7/0397; C08F 220/283; G03F 7/325; G03F 7/2004

(57) ABSTRACT

A resist composition which contains a polymer compound having a constitutional unit (a01) represented by General Formula (a01-1), which contains a specific acid dissociable group represented by General Formula (a01-r-1) and a constitutional unit (a02) represented by General Formula (a02-1), which contains a specific cyanolactone structure, a proportion of the constitutional unit (a01) is more than 50% by mole and 70% by mole or less

[chemical structure]

### BACKGROUND OF THE INVENTION

### Field of the Invention

The present invention relates to a resist composition and a method of forming a resist pattern.

Priority is claimed on Japanese Patent Application No. 2019-204241, filed on Nov. 11, 2019, the content of which is incorporated herein by reference.

### DESCRIPTION OF RELATED ART

In recent years, in the production of semiconductor elements and liquid crystal display elements, advances in lithography techniques have led to rapid progress in the field of pattern miniaturization. Typically, these miniaturization techniques involve shortening the wavelength (increasing the energy) of the light source for exposure.

Resist materials for use with these types of light sources for exposure require lithography characteristics such as a high resolution capable of reproducing patterns of minute dimensions, and a high level of sensitivity to these types of light sources for exposure.

As a resist material that satisfies these requirements, in the related art, a chemical amplification type resist composition that contains a base material component exhibiting changed solubility in a developing solution under action of acid, and an acid generator component that generates an acid upon exposure has been used.

In the chemical amplification type resist composition, a resin having a plurality of constitutional units is generally used in order to improve the lithography characteristics and the like.

For example, Japanese Unexamined Patent Application, First Publication No. 2018-106158 discloses a resist composition or the like that employs a polymer compound having two specific constitutional units to improve lithography characteristics.

### CITATION LIST

### Patent Literature

[Patent Literature 1] Japanese Unexamined Patent Application, First Publication No. 2018-106158

### SUMMARY OF THE INVENTION

With the further progresses of lithography techniques and the resist pattern miniaturization, a resist composition is required to have further improved lithography characteristics. Among them, the in-plane uniformity (CDU) of pattern dimensions is often emphasized as the characteristic of resist. Here, the “critical dimension uniformity (CDU)” is a standard deviation value of the hole diameters obtained by measuring the diameter of each hole in a fine pattern, for example, a hole pattern in the case of a contact hole (CH) pattern. It is preferable that the smaller the standard deviation value of the hole diameters is, the higher the in-plane uniformity of pattern dimensions is.

In addition, with the resist pattern being miniaturized, the resist film becomes thinner, and thus it is necessary to improve the etching resistance when performing etching by using the patterned portion as a mask.

The present invention has been made in consideration of the above circumstances, an object of the present invention is to provide a resist composition excellent in CDU and etching resistance and a method of forming a resist pattern by using the resist composition.

In order to achieve the above-described object, the present invention employs the following configurations.

That is, the first aspect of the present invention is a resist composition which generates an acid upon exposure and exhibits changed solubility in a developing solution under action of acid. The resist composition contains a resin component (A1) exhibiting changed solubility in a developing solution under action of acid. The resin component (A1) contains a polymer compound having a constitutional unit (a01) represented by General Formula (a01-1) and a constitutional unit (a02) represented by General Formula (a02-1), and a proportion of the constitutional unit (a01) is more than 50% by mole and 70% by mole or less with respect to a total amount (100% by mole) of all constitutional units constituting the polymer compound.

[chemical structure]

[In Formula (a01-1), R represents a hydrogen atom, an alkyl group having 1 to 5 carbon atoms, or a halogenated alkyl group having 1 to 5 carbon atoms. Va⁰¹ represents a divalent hydrocarbon group which may have an ether bond. nₐ₀₁ represents an integer of 0 to 2. Ra⁰⁰ is an acid dissociable group represented by General Formula (a01-r-1).

In Formula (a01-r-1), Ra⁰⁰¹ to Ra⁰⁰³ each independently represent a hydrocarbon group, and Ra⁰⁰² and Ra⁰⁰³ may be bonded with each independently other to form a ring. * represents a bonding site.]

[chemical structure]

[In Formula (a02-1), R represents a hydrogen atom, an alkyl group having 1 to 5 carbon atoms, or a halogenated alkyl group having 1 to 5 carbon atoms. Va⁰² represents a divalent hydrocarbon group which may have a substituent. nₐ₀₂ represents an integer of 0 to 2. Ra¹ and Ra² each independently represent a hydrogen atom, an alkyl group having 1 to 5 carbon atoms, an alkoxy group, or an alkylthio group, or Ra¹ and Ra² may be bonded to each other to form an alkylene group having 1 to 6 carbon atoms, which may contain an oxygen atom or sulfur atom, an ether bond, or a thioether bond. Ra⁰¹ represents a halogen atom, an alkyl group having 1 to 6 carbon atoms, which may have a halogen atom, a hydroxyalkyl group having 1 to 6 carbon atoms, in which a hydroxy moiety may be protected by a protecting group and which may have a halogen atom, a carboxy group which may form a salt, or a substituted oxycarbonyl group. p₀ represents an integer of 0 to 8. In a case where two or more Ra′⁰¹'s are present, a plurality of Ra′⁰¹'s may be the same or different from each other. q₀₁ represents an integer of 1 to 9.]

The second aspect of the present invention is a method of forming a resist pattern, including a step of forming a resist film on a support using the resist composition according to the first aspect, a step of exposing the resist film, and a step of developing the exposed resist film to form a resist pattern.

According to the present invention, a resist composition excellent in CDU and etching resistance and a method of forming a resist pattern by using the resist composition can be provided.

### DETAILED DESCRIPTION OF THE INVENTION

In the present specification and the scope of the present patent claims, the term “aliphatic” is a relative concept used with respect to the term “aromatic” and defines a group or compound that has no aromaticity.

The term “alkyl group” contains a monovalent saturated hydrocarbon group that is linear, branched, or cyclic, unless otherwise specified. The same applies to the alkyl group in an alkoxy group.

The term “alkylene group” contains a divalent saturated hydrocarbon group that is linear, branched, or cyclic, unless otherwise specified.

Examples of the “halogen atom” include a fluorine atom, a chlorine atom, a bromine atom, and an iodine atom. The term “constitutional unit” means a monomer unit (monomeric unit) that contributes to the formation of a polymer compound (a resin, a polymer, or a copolymer).

In a case where “may have a substituent” is described, both of a case where a monovalent group is substituted for a hydrogen atom (—H) and a case where a divalent group is substituted for a methylene (—CH₂—) group are included.

The term “exposure” is used as a general concept that includes irradiation with any form of radiation.

The term “acid decomposable group” indicates a group having an acid decomposability, in which at least a part of a bond in the structure of the acid decomposable group can be cleaved by an action of an acid.

Examples of the acid decomposable group having a polarity which is increased by an action of an acid include groups which are decomposed by an action of an acid to generate a polar group.

Examples of the polar group include a carboxy group, a hydroxy group, an amino group, and a sulfo group (—SO₃H).

More specific examples of the acid decomposable group include a group in which the above-described polar group has been protected by an acid dissociable group (for example, a group in which a hydrogen atom of the OH-containing polar group has been protected by an acid dissociable group).

The “acid dissociable group” indicates both (i) a group having an acid dissociability, in which a bond between the acid dissociable group and an atom adjacent to the acid dissociable group can be cleaved by an action of an acid; and (ii) a group in which some bonds are cleaved by an action of an acid, and then a decarboxylation reaction occurs, thereby cleaving the bond between the acid dissociable group and the atom adjacent to the acid dissociable group.

It is necessary that the acid dissociable group that constitutes the acid decomposable group is a group which exhibits a polarity lower than the polarity of the polar group generated by the dissociation of the acid dissociable group. Accordingly, in a case where the acid dissociable group is dissociated by an action of an acid, a polar group which exhibits a polarity higher than the polarity of the acid dissociable group is generated, thereby increasing the polarity. As a result, the polarity of the entire component (A1) is increased. By the increase in the polarity, the solubility in a developing solution relatively changes. The solubility is increased in a case where the developing solution is an alkali developing solution, whereas the solubility is decreased in a case where the developing solution is an organic developing solution.

The “base material component” is an organic compound having a film forming ability. The organic compounds used as the base material component are roughly classified into a non-polymer and a polymer. As the non-polymer, those having a molecular weight of 500 or more and less than 4,000 are usually used. Hereinafter, a “low molecular compound” refers to a non-polymer having a molecular weight of 500 or more and less than 4,000. As the polymer, those having a molecular weight of 1,000 or more are usually used. Hereinafter, “resin”, “polymer compound”, or “polymer” refers to a polymer having a molecular weight of 1,000 or more. As the molecular weight of the polymer, a polystyrene-equivalent mass-average molecular weight determined by gel permeation chromatography (GPC) is used.

A “constitutional unit derived from” means a constitutional unit that is formed by the cleavage of a multiple bond between carbon atoms, for example, an ethylenic double bond.

In the acrylic acid ester, the hydrogen atom bonded to the carbon atom at the ex-position may be substituted with a substituent. The substituent (R®*) that is substituted for the hydrogen atom bonded to the carbon atom at the α-position is an atom other than a hydrogen atom or a group. Further, an itaconic acid diester in which the substituent (R^{αx}) is substituted with a substituent having an ester bond or an α-hydroxyacryl ester in which the substituent (R^{αx}) is substituted with a hydroxyalkyl group or a group obtained by modifying a hydroxy group thereof can be mentioned as the acrylic acid ester. A carbon atom at the α-position of the acrylic acid ester indicates the carbon atom bonded to the carbonyl group of acrylic acid, unless otherwise specified.

Hereinafter, an acrylic acid ester in which the hydrogen atom bonded to the carbon atom at the α-position is substituted with a substituent is also referred to as the α-substituted acrylic acid ester”.

The term “derivative” includes those in which the hydrogen atom at the ex-position of an object compound has been substituted with other substituents such as an alkyl group and a halogenated alkyl group; and derivatives thereof. Examples of the derivatives thereof include: a derivative in which the hydrogen atom of the hydroxy group of the object compound in which the hydrogen atom at the α-position may be substituted with an organic group; and a derivative in which a substituent other than a hydroxy group is bonded to the object compound in which the hydrogen atom at the α-position may be substituted with a substituent The α-position refers to the first carbon atom adjacent to the functional group unless otherwise specified.

Examples of the substituent that is substituted for the hydrogen atom at the α-position of hydroxystyrene include the same group as R^{αx}.

In the present specification and the scope of the present patent claims, an asymmetric carbon may be present or enantiomers or diastereomers may be present depending on the structure of the chemical formula. In that case, these isomers are represented by one chemical formula. These isomers may be used alone or in the form of a mixture.

(Resist Composition)

The resist composition according to the first aspect of the present invention is a resist composition which generates an acid upon exposure and exhibits changed solubility in a developing solution under action of acid. The resist composition contains a base material component (A) (hereinafter also referred to as component (A)) having a solubility in a developing solution, which is changed by an action of an acid.

In a case where a resist film is formed using the resist composition of the present embodiment and the formed resist film is subjected to selective exposure, an acid is generated at the exposed portion of the resist film, and the generated acid acts on the component (A) to change the solubility of the component (A) in a developing solution, whereas the solubility of the component (A) in the developing solution is not changed at the unexposed portion of the resist film, thereby generating the difference in solubility in the developing solution between the exposed portion and the unexposed portion of the resist film.

The resist composition of the present embodiment may be a positive-tone resist composition or a negative-tone resist composition.

Further, in the formation of a resist pattern, the resist composition of the present embodiment can be applied to an alkali developing process using an alkali developing solution in the developing treatment, or a solvent developing process using a developing solution containing an organic solvent (organic developing solution) in the developing treatment.

That is, the resist composition of the present embodiment is a “positive-tone resist composition for an alkali developing process” that forms a positive-tone resist pattern in an alkali developing process, and a “negative-tone resist composition for a solvent developing process” that forms a negative-tone resist pattern in a solvent developing process.

<Component (A)>

In the resist composition of the present embodiment, the component (A) contains a resin component (A1) (hereinafter, also referred to as “component (A1)”) exhibiting changed solubility in a developing solution under action of acid. The component (A1) contains a polymer compound having a constitutional unit (a01) represented by General Formula (a01-1) and a constitutional unit (a02) represented by General Formula (a02-1).

As the component (A), at least the component (A1) is used, and at least other polymer compound and a low molecular compound may be used in combination with the component (A1).

In the resist composition of the present embodiment, the component (A) may be used alone or in a combination of two or more kinds thereof.

In regard to component (A1)

The component (A1) contains a polymer compound having the constitutional unit (a01) and the constitutional unit (a02).

“Constitutional Unit (a01)”

The constitutional unit (a01) is a constitutional unit represented by General Formula (a01-1).

[chemical structure]

[In Formula (a01-1), R represents a hydrogen atom, an alkyl group having 1 to 5 carbon atoms, or a halogenated alkyl group having 1 to 5 carbon atoms. Va⁰¹ represents a divalent hydrocarbon group which may have an ether bond. nₐ₀₁ represents an integer of 0 to 2. Ra⁰⁰ is an acid dissociable group represented by General Formula (a01-r-1).

In Formula (a01-r-1), Ra⁰⁰¹ to Ra⁰⁰³ each independently represent a hydrocarbon group, and Ra⁰⁰² and Ra⁰⁰³ may be bonded with each independently other to form a ring. * represents a bonding site.]

In Formula (a01-1), R represents a hydrogen atom, an alkyl group having 1 to 5 carbon atoms, or a halogenated alkyl group having 1 to 5 carbon atoms. The alkyl group having 1 to 5 carbon atoms as R is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms is a group in which a part or all hydrogen atoms in the alkyl group having 1 to 5 carbon atoms have been substituted with halogen atoms. The halogen atom is particularly preferably a fluorine atom.

R is preferably a hydrogen atom, an alkyl group having 1 to 5 carbon atoms, or a fluorinated alkyl group having 1 to 5 carbon atoms, and most preferably a hydrogen atom or a methyl group in terms of industrial availability.

In Formula (a01-1), Va⁰¹ represents a divalent hydrocarbon group which may have an ether bond. The divalent hydrocarbon group may be an aliphatic hydrocarbon group or an aromatic hydrocarbon group.

The aliphatic hydrocarbon group as the divalent hydrocarbon group represented by Va⁰¹ may be saturated or unsaturated. In general, the aliphatic hydrocarbon group is preferably saturated.

More specific examples of the aliphatic hydrocarbon group include a linear or branched aliphatic hydrocarbon group and an aliphatic hydrocarbon group containing a ring in the structure thereof.

The linear aliphatic hydrocarbon group described above has preferably 1 to 10 carbon atoms, more preferably 1 to 6 carbon atoms, still more preferably 1 to 4 carbon atoms, and most preferably 1 to 3 carbon atoms. The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group described above has preferably 2 to 10 carbon atoms, more preferably 3 to 6 carbon atoms, still more preferably 3 or 4 carbon atoms, and most preferably 3 carbon atoms. The branched aliphatic hydrocarbon group is preferably a branched alkylene group, and specific examples thereof include alkylalkylene groups; for example, alkylmethylene groups such as —CH(CH₃)—, —CH(CH₂CH₃>, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. The alkyl group in the alkylalkylene group is preferably a linear alkyl group having 1 to 5 carbon atoms.

Examples of the aliphatic hydrocarbon group containing a ring in the structure thereof include an alicyclic hydrocarbon group (a group in which two hydrogen atoms have been removed from an aliphatic hydrocarbon ring), a group in which the alicyclic hydrocarbon group is bonded to the terminal of the above-described linear or branched aliphatic hydrocarbon group, and a group in which the alicyclic hydrocarbon group is interposed in the above-described linear or branched aliphatic hydrocarbon group. Examples of the above-described linear or branched aliphatic hydrocarbon group include the same group as the above-described linear aliphatic hydrocarbon group or above-described branched aliphatic hydrocarbon group.

The alicyclic hydrocarbon group has preferably 3 to 20 carbon atoms and more preferably 3 to 12 carbon atoms.

The alicyclic hydrocarbon group may be monocyclic or polycyclic. The monocyclic alicyclic hydrocarbon group is preferably a group in which two hydrogen atoms have been removed from a monocycloalkane. The monocycloalkane has preferably 3 to 6 carbon atoms, and specific examples thereof include cyclopentane, and cyclohexane. The polycyclic alicyclic hydrocarbon group is preferably a group in which two hydrogen atoms have been removed from a polycycloalkane. The polycycloalkane is preferably a group having 7 to 12 carbon atoms, and specific examples thereof include adamantane, norbornane, isobomane, tricyclodecane, and tetracyclododecane.

The aromatic hydrocarbon group as the divalent hydrocarbon group represented by Va⁰¹ is a hydrocarbon group having an aromatic ring.

The aromatic hydrocarbon group has preferably 3 to 30 carbon atoms, more preferably 5 to 30 carbon atoms, still more preferably 5 to 20 carbon atoms, particularly preferably 6 to 15 carbon atoms, and most preferably 6 to 12 carbon atoms. However, the number of carbon atoms in a substituent is not included in the number of carbon atoms. Specific examples of the aromatic ring which the aromatic hydrocarbon group has include: aromatic hydrocarbon rings such as benzene, biphenyl, fluorene, naphthalene, anthracene, and phenanthrene; and aromatic hetero rings in which a part of carbon atoms constituting the above-described aromatic hydrocarbon rings have been substituted with hetero atoms. Examples of the hetero atom in the aromatic hetero rings include an oxygen atom, a sulfur atom, and a nitrogen atom.

Specific examples of the aromatic hydrocarbon group include: a group in which two hydrogen atoms have been removed from the above-described aromatic hydrocarbon ring (an arylene group); and a group in which one hydrogen atom of a group (an aryl group) formed by removing one hydrogen atom from the aromatic hydrocarbon ring has been substituted with an alkylene group (for example, a group formed by further removing one hydrogen atom from an aryl group of an arylalkyl group such as a benzyl group, a phenethyl group, a 1-naphthylmethyl group, a 2-naphthylmethyl group, a 1-naphthylethyl group, or a 2-naphthylethyl group). The alkylene group (an alkyl chain in the arylalkyl group) has preferably 1 to 4 carbon atoms, more preferably 1 or 2 carbon atoms, and particularly preferably 1 carbon atom.

In Formula (a01-1), nₐ₀₁ represents an integer of 0 to 2, preferably 0 or 1, and more preferably 0.

In Formula (a01-1), Ra⁰⁰ represents an acid dissociable group represented by General Formula (a01-r-1).

Ra⁰⁰¹ to Ra⁰⁰³ in Formula (a01-r-1) each independently represent a hydrocarbon group. Examples of the hydrocarbon group include a linear or branched alkyl group, a chain-like or cyclic alkenyl group, or a cyclic hydrocarbon group.

The linear alkyl group has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group has preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group. Among these, an isopropyl group preferable.

In a case where Ra⁰⁰¹ to Ra⁰⁰³ represents a cyclic hydrocarbon group, the cyclic hydrocarbon group may be an aliphatic hydrocarbon group or an aromatic hydrocarbon group and may be a polycyclic group or a monocyclic group.

The aliphatic hydrocarbon group which is a monocyclic group is preferably a group in which one hydrogen atom has been removed from a monocycloalkane. The monocycloalkane has preferably 3 to 6 carbon atoms, and specific examples thereof include cyclopentane and cyclohexane.

The aliphatic hydrocarbon group which is a polycyclic group is preferably a group in which one hydrogen atom has been removed from a polycycloalkane. The polycycloalkane is preferably a group having 7 to 12 carbon atoms, and specific examples of thereof include adamantane, norbomane, isobornane, tricyclodecane, and tetracyclododecane.

In a case where the cyclic hydrocarbon group as Ra⁰⁰¹ to Ra⁰⁰³ is an aromatic hydrocarbon group, the aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring has preferably 5 to 30 carbon atoms, more preferably 5 to 20 carbon atoms, still more preferably 6 to 15 carbon atoms, and particularly preferably 6 to 12 carbon atoms. Specific examples of the aromatic ring include: aromatic hydrocarbon rings such as benzene, naphthalene, anthracene, and phenanthrene; and aromatic hetero rings in which a part of carbon atoms constituting the above-described aromatic hydrocarbon rings have been substituted with hetero atoms. Examples of the hetero atom in the aromatic hetero rings include an oxygen atom, a sulfur atom, and a nitrogen atom. Specific examples of the aromatic hetero ring include a pyridine ring and a thiophene ring.

Specific examples of the aromatic hydrocarbon group as Ra⁰⁰¹ to Ra⁰⁰³ include: a group in which one hydrogen atom has been removed from the above-described aromatic hydrocarbon ring or aromatic hetero ring (an aryl group or a heteroaryl group); a group in which one hydrogen atom has been removed from an aromatic compound having two or more aromatic rings (biphenyl, fluorene or the like); and a group in which one hydrogen atom of the above-described aromatic hydrocarbon ring or aromatic hetero ring has been substituted with an alkylene group (for example, an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aromatic hydrocarbon ring or aromatic hetero ring has preferably 1 to 4 carbon atoms, more preferably 1 or 2 carbon atoms, and particularly preferably 1 carbon atom.

The cyclic hydrocarbon group as Ra⁰⁰¹ to Ra⁰⁰³ may have a substituent. Examples of the substituent include, —R^{P1}, —R^{P2}—O—R^{P1}, —R^{P2}—CO—R^{P1}, —R^{P2}—CO—OR^{P1}, —R^{P2}—O—CO—R^{P1}, —R^{P2}—OH, —R^{P2}—CN, and —R^{P2}—COOH (hereinafter, these substituents are also collectively referred to as “Ra^{x0}”).

Here, R^{P1} represents a monovalent chain-like saturated hydrocarbon group having 1 to 10 carbon atoms, a monovalent aliphatic cyclic saturated hydrocarbon group having 3 to 20 carbon atoms, or a monovalent aromatic hydrocarbon group having 6 to 30 carbon atoms. In addition, R^{P2} represents a single bond, a divalent chain-like saturated hydrocarbon group having 1 to 10 carbon atoms, a divalent aliphatic cyclic saturated hydrocarbon group having 3 to 20 carbon atoms, or a divalent aromatic hydrocarbon group having 6 to 30 carbon atoms. However, a part or all of the hydrogen atoms contained in the chain-like saturated hydrocarbon group, aliphatic cyclic saturated hydrocarbon group, and aromatic hydrocarbon group of R^{P1} and R^{P2} may be substituted with fluorine atoms. In the aliphatic cyclic hydrocarbon group, one or more of the above-described substituents may be included as a single kind, or one or more of the above-described substituents may be included as a plurality of kinds.

Examples of the monovalent chain-like saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms include: monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and cyclododecyl group; and polycyclic aliphatic saturated hydrocarbon groups such as a bicyclo[2.2.2]octanyl group, a tricyclo[5.2.1.02,6]decanyl group, a tricyclo [3.3.1.13,7]decanyl group, a tetracyclo[6.2.1.13,6.02,7] dodecanyl group, and an adamantyl group.

Examples of the monovalent aromatic hydrocarbon group having 6 to 30 carbon atoms include groups in which one hydrogen atom has been removed from aromatic hydrocarbon rings such as benzene, biphenyl, fluorene, naphthalene, anthracene, and phenanthrene.

In a case where Ra⁰⁰² and Ra⁰⁰³ are bonded to each other to form a ring, groups represented by General Formula (a01-r2-1), General Formula (a01-r2-2), and General Formula (a01-r2-3) can be suitably mentioned.

On the other hand, in a case where Ra⁰⁰² and Ra⁰⁰³ are not bonded to each other and represent an independent hydrocarbon group, a group represented by General Formula (a01-r2-4) can be suitably mentioned.

[chemical structure]

[In Formula (a01-r2-1), Ra′¹⁰ represents a linear or branched alkyl group having 1 to 12 carbon atoms, a part of which may be substituted with a halogen atom or a hetero atom-containing group. Ra′¹¹ represents a group that forms an aliphatic cyclic group together with a carbon atom to which Ra′¹⁰ is bonded. In Formula (a01-r2-2), Ya represents a carbon atom. Xa is a group that forms a cyclic hydrocarbon group together with Ya. A part or all of the hydrogen atoms that the cyclic hydrocarbon group has may be substituted. Ra¹⁰¹ to Ra¹⁰³ each independently represent a hydrogen atom, a monovalent chain-like saturated hydrocarbon group having 1 to 10 carbon atoms, or a monovalent aliphatic cyclic saturated hydrocarbon group having 3 to 20 carbon atoms. A part or all of the hydrogen atoms that the chain-like saturated hydrocarbon group and the aliphatic cyclic saturated hydrocarbon group have may be substituted. Two or more of Ra¹⁰¹ to Ra¹⁰³ may be bonded to each other to form a cyclic structure. In Formula (a01-r2-3), Yaa represents a carbon atom. Xaa is a group that forms an aliphatic cyclic group together with Yaa. Ra¹⁰⁴ represents an aromatic hydrocarbon group which may have a substituent. In Formula (a01-r2-4), Ra′¹² and Ra′¹³ each independently represent a monovalent chain-like saturated hydrocarbon group having 1 to 10 carbon atoms or a hydrogen atom. A part or all of the hydrogen atoms that the chain-like saturated hydrocarbon group has may be substituted. Ra′¹⁴ represents a hydrocarbon group which may have a substituent. * represents a bonding site.]

In Formula (a01-r2-1), Ra′¹⁰ represents a linear or branched alkyl group having 1 to 12 carbon atoms, a part of which may be substituted with a halogen atom or a hetero atom-containing group.

The linear alkyl group as Ra′¹⁰ has 1 to 12 carbon atoms, and has preferably 1 to 10 carbon atoms and particularly preferably 1 to 5 carbon atoms.

Examples of the branched alkyl group as Ra¹⁰ includes the same group as the branched alkyl group as Ra⁰⁰¹ in Formula (a01-r-1).

A part of the alkyl group as Ra′¹⁰ may be substituted with a halogen atom or a hetero atom-containing group. For example, a part of the hydrogen atoms constituting the alkyl group may be substituted with a halogen atom or a hetero atom-containing group. Further, a part of carbon atoms (methylene group and the like) constituting the alkyl group may be substituted with a hetero atom-containing group.

Examples of the hetero atom mentioned here include an oxygen atom, a sulfur atom, and a nitrogen atom. Examples of the hetero atom-containing group include —O—, —C(═O)—O—, —O—C(═O)—, —C(═O)—, —O—C(═O)—O—, —C(═O)—NH—, —NH—, —S—, —S(═O)₂—, and —S(═O)₂—O—.

In Formula (a01-r2-1), Ra′¹¹ (an aliphatic cyclic group that is formed together with the carbon atom to which Ra′¹⁰ is bonded) is preferably the group mentioned as the aliphatic hydrocarbon group (alicyclic hydrocarbon group) which is a monocyclic group or a polycyclic group as Ra⁰⁰¹ in Formula (a01-r-1). Among them, a monocyclic alicyclic hydrocarbon group is preferable, and specifically, a cyclopentyl group and a cyclohexyl group are more preferable, and a cyclopentyl group is still more preferable.

In Formula (a01-r2-2), examples of the cyclic hydrocarbon group formed by Xa together with Ya include groups in which one or more hydrogen atoms are further removed from a monovalent cyclic hydrocarbon group (an aliphatic hydrocarbon group) as Ra⁰⁰¹ in Formula (a01-r-1).

The cyclic hydrocarbon group that is formed by Xa together with Ya may have a substituent. Examples of this substituent include the same group as the substituent which may be included in the cyclic hydrocarbon group as Ra⁰⁰¹ in Formula (a01-r-1). In Formula (a01-r2-2), as Ra¹⁰¹ to Ra¹⁰³, examples of the monovalent chain-like saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms, as Ra¹⁰¹ to Ra¹⁰³, include: monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and cyclododecyl group; and polycyclic aliphatic saturated hydrocarbon groups such as a bicyclo[2.2.2]octanyl group, a tricyclo[5.2.1.02,6]decanyl group, a tricyclo [3.3.1.13,7]decanyl group, a tetracyclo[6.2.1.13,6.02,7] dodecanyl group, and an adamantyl group.

Among them, Ra¹⁰¹ to Ra¹⁰³ are preferably a hydrogen atom or a monovalent chain-like saturated hydrocarbon group having 1 to 10 carbon atoms, from the viewpoint of the easy synthesis. Among them, a hydrogen atom, a methyl group, and an ethyl group are more preferable, and a hydrogen atom is particularly preferable.

Examples of the substituent which the chain-like saturated hydrocarbon group represented by Ra¹⁰¹ to Ra¹⁰³ or the aliphatic cyclic saturated hydrocarbon group has include the same groups as Ra^{x0} described above.

Examples of the group including a carbon-carbon double bond generated by forming a cyclic structure, in which two or more of Ra¹⁰¹ to Ra¹⁰³ are bonded to each other, include a cyclopentenyl group, a cyclohexenyl group, a methylcyclopentenyl group, a methylcyclohexenyl group, a cyclopentylideneethenyl group, and a cyclohexylideneethenyl group. Among these, a cyclopentenyl group, a cyclohexenyl group, and a cyclopentylideneethenyl group are preferable from the viewpoint of easy synthesis.

In Formula (a01-r2-3), an aliphatic cyclic group that is formed by Xaa together with Yaa is preferably the group mentioned as the aliphatic hydrocarbon group which is a monocyclic group or a polycyclic group as Ra⁰⁰¹ in Formula (a01-r-1).

In Formula (a01-r2-3), examples of the aromatic hydrocarbon group as Ra¹⁰⁴ include groups in which one or more hydrogen atoms have been removed from an aromatic hydrocarbon ring having 5 to 30 carbon atoms. Among them, Ra¹⁰⁴ is preferably a group in which one or more hydrogen atoms have been removed from an aromatic hydrocarbon ring having 6 to 15 carbon atoms, more preferably a group in which one or more hydrogen atoms have been removed from benzene, naphthalene, anthracene, or phenanthrene, still more preferably a group in which one or more hydrogen atoms have been removed from benzene, naphthalene, or anthracene, particularly preferably a group in which one or more hydrogen atoms have been removed from benzene or naphthalene, and most preferably a group in which one or more hydrogen atoms have been removed from benzene.

Examples of the substituent which Ra¹⁰⁴ in Formula (a01-r2-3) may have include a methyl group, an ethyl group, propyl group, a hydroxy group, a carboxy group, a halogen atom, an alkoxy group (a methoxy group, an ethoxy group, a propoxy group, a butoxy group, and the like), and an alkyloxycarbonyl group.

In Formula (a01-r2-4), Ra′¹² and Ra′¹³ each independently represent a monovalent chain-like saturated hydrocarbon group having 1 to 10 carbon atoms or a hydrogen atom. Examples of the monovalent chain-like saturated hydrocarbon group having 1 to 10 carbon atoms as Ra′¹² and Ra′¹³ include the same monovalent chain-like saturated hydrocarbon groups as those having 1 to 10 carbon atoms as Ra¹⁰¹ to Ra¹⁰³ as described above. A part or all of the hydrogen atoms that the chain-like saturated hydrocarbon group has may be substituted.

Among them, Ra′¹² and Ra′¹³ are preferably a hydrogen atom or an alkyl group having 1 to 5 carbon atoms, more preferably an alkyl group having 1 to 5 carbon atoms, still more preferably a methyl group or an ethyl group, and particularly preferably a methyl group.

In a case where the chain-like saturated hydrocarbon groups represented by Ra′¹² and Ra′¹³ are substituted, examples of the substituent include the same group as Ra^{x0} described above.

In Formula (a01-r2-4), Ra′¹⁴ represents a hydrocarbon group which may have a substituent. Examples of the hydrocarbon group as Ra′¹⁴ include a linear or branched alkyl group and a cyclic hydrocarbon group.

The linear alkyl group as Ra′¹⁴ has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group as Ra′¹⁴ has preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group. Among these, an isopropyl group is preferable.

In a case where Ra′¹⁴ represents a cyclic hydrocarbon group, the cyclic hydrocarbon group may be an aliphatic hydrocarbon group or an aromatic hydrocarbon group and may be a polycyclic group or a monocyclic group.

The aliphatic hydrocarbon group which is a monocyclic group is preferably a group in which one hydrogen atom has been removed from a monocycloalkane. The monocycloalkane has preferably 3 to 6 carbon atoms, and specific examples thereof include cyclopentane and cyclohexane.

The aliphatic hydrocarbon group which is a polycyclic group is preferably a group in which one hydrogen atom has been removed from a polycycloalkane. The polycycloalkane is preferably a group having 7 to 12 carbon atoms, and specific examples of thereof include adamantane, norbomane, isobornane, tricyclodecane, and tetracyclododecane.

Examples of the aromatic hydrocarbon group as Ra′¹⁴ include the same group as the aromatic hydrocarbon group as Ra¹⁰⁴. Among them, Ra′¹⁴ is preferably a group in which one or more hydrogen atoms have been removed from an aromatic hydrocarbon ring having 6 to 15 carbon atoms, more preferably a group in which one or more hydrogen atoms have been removed from benzene, naphthalene, anthracene, or phenanthrene, still more preferably a group in which one or more hydrogen atoms have been removed from benzene, naphthalene, or anthracene, particularly preferably a group in which one or more hydrogen atoms have been removed from naphthalene or anthracene, and most preferably a group in which one or more hydrogen atoms have been removed from naphthalene.

Examples of the substituent which may be included in Ra′¹⁴ include the same group as the substituent which may be included in Ra¹⁰⁴.

In a case where Ra′¹⁴ in Formula (a01-r2-4) is a naphthyl group, the position at which the tertiary carbon atom in Formula (a01-r2-4) is bonded may be any one of the 1-position and the 2-position of the naphthyl group.

In a case where Ra′¹⁴ in Formula (a01-r2-4) is an anthryl group, the position at which the tertiary carbon atom in Formula (a01-r2-4) is bonded may be any one of the 1-position, the 2-position, and the 9-position of the anthryl group.

Specific examples of the group represented by Formula (a01-r2-1) are as follows.

[chemical structure]

[chemical structure]

[chemical structure]

[chemical structure]

[chemical structure]

Specific examples of the group represented by Formula (a01-r2-2) are as follows.

[chemical structure]

[chemical structure]

[chemical structure]

[chemical structure]

[chemical structure]

Specific examples of the group represented by Formula (a01-r2-3) are as follows.

[chemical structure]

[chemical structure]

Specific examples of the group represented by Formula (a01-r2-4) are as follows.

[chemical structure]

[chemical structure]

[chemical structure]

In Formula (a01-1), Ra⁰⁰ is preferably, among the above, an acid dissociable group represented by General Formula (a01-r-11). 10 [0072]

[chemical structure]

[In Formula (a01-r-11), Ya¹¹ represents a carbon atom. Xa¹¹ represents a group that forms a monocyclic alicyclic hydrocarbon group together with Ya¹¹. A part or all of the hydrogen atoms that the monocyclic alicyclic hydrocarbon group has may be substituted. Ra¹¹ represents a hydrocarbon group which may have a substituent. * represents a bonding site.]

In Formula (a01-r-11), examples of the monocyclic alicyclic hydrocarbon group that is formed by Xa¹¹ together with Ya¹¹ include the same groups as those mentioned as the monocyclic aliphatic hydrocarbon groups as Ra⁰⁰¹ in Formula (a01-r-1). Examples of the hydrocarbon group as Ra¹¹, which may have a substituent, include the same groups as the hydrocarbon groups as Ra⁰⁰¹ in Formula (a01-r-1), which may have a substituent.

Suitable specific examples of the group represented by Formula (a01-r-11) include groups respectively represented by Formulae (r-pr-s1) to (r-pr-s20), (r-pr-sp1) to (r-pr-sp4), (r-pr-sv1) to (r-pr-sv12), and (r-pr-sa1) to (r-pr-sa9).

Suitable specific examples of the constitutional unit (a01) are as follows. In the following formulae, R^{α} represents a hydrogen atom, a methyl group, or a trifluoromethyl group.

[chemical structure]

The constitutional unit (a01) that the component (A1) has may be one kind or may be two or more kinds.

The proportion of the constitutional unit (a01) in the component (A1) is more than 50% by mole and 70% by mole or less, and is preferably 52% by mole or more and 70% by mole or less, and more preferably 55% by mole or more and 70% by mole or less, with respect to the total amount (100% by mole) of all constitutional units constituting the component (A1).

In a case where the proportion of the constitutional unit (a01) is equal to or greater than the lower limit of the preferred range described above, lithography characteristics such as sensitivity, resolution, and roughness are improved. In addition, in a case where the proportion is equal to or lower than the upper limit of the preferred range, balance with other constitutional units can be obtained, and various lithography characteristics are improved.

“Constitutional Unit (a02)”

The constitutional unit (a02) is a constitutional unit represented by General Formula (a02-1).

[chemical structure]

[In Formula (a02-1), R represents a hydrogen atom, an alkyl group having 1 to 5 carbon atoms, or a halogenated alkyl group having 1 to 5 carbon atoms. Va⁰² represents a divalent hydrocarbon group which may have a substituent. nₐ₀₂ represents an integer of 0 to 2. Ra¹ and Ra² each independently represent a hydrogen atom, an alkyl group having 1 to 5 carbon atoms, an alkoxy group, or an alkylthio group, or Ra¹ and Ra² may be bonded to each other to form an alkylene group having 1 to 6 carbon atoms, which may contain an oxygen atom or sulfur atom, an ether bond, or a thioether bond. Ra⁰¹ represents a halogen atom, an alkyl group having 1 to 6 carbon atoms, which may have a halogen atom, a hydroxyalkyl group having 1 to 6 carbon atoms, in which a hydroxy moiety may be protected by a protecting group and which may have a halogen atom, a carboxy group which may form a salt, or a substituted oxycarbonyl group, p₀ represents an integer of 0 to 8. In a case where two or more Ra′⁰¹'s are present, a plurality of Ra′⁰¹'s may be the same or different from each other. q₀₁ represents an integer of 1 to 9.]

Examples of R in General Formula (a02-1) include the same groups as R in General Formula (a01-1).

Examples of Va⁰² in General Formula (a01-1) include the same groups as R in General Formula (a01-1).

In General Formula (a02-1), nₐ₀₂ represents an integer of 0 to 2, preferably 0 or 1, and more preferably 0.

In General Formula (a02-1) Ra¹ and Ra² each independently represent a hydrogen atom, an alkyl group having 1 to 5 carbon atoms, an alkoxy group, or an alkylthio group, or Ra¹ and Ra² may be bonded to each other to form an alkylene group having 1 to 6 carbon atoms, which may contain an oxygen atom or sulfur atom, an ether bond, or a thioether bond.

The alkyl group having 1 to 5 carbon atoms as Ra¹ and Ra² is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group.

The alkoxy group as Ra¹ and Ra² is preferably linear or branched, and specific examples thereof include groups formed by linking the alkyl group mentioned as the alkyl group as Ra¹ and Ra² with an oxygen atom (—O—).

The alkylthio group as Ra¹ and Ra² preferably has 1 to 4 carbon atoms, and specific examples thereof include a methylthio group, an ethylthio group, an n-propylthio group, an iso-propylthio group, an n-butylthio group, and a tert-butylthio group.

The alkylene group having 1 to 6 carbon atoms, which is formed by bonding Ra¹ and Ra² to each other, is preferably a linear or branched alkylene group, and examples thereof include a methylene group, an ethylene group, an n-propylene group, and an isopropylene group. Specific examples of the alkylene group that contains an oxygen atom or a sulfur atom include groups in which —O— or —S— is interposed in the terminal of the alkylene group or between the carbon atoms of the alkylene group, and examples thereof include —O—CH₂—, —CH₂—O—CH₂—, —S—CH₂—, and —CH₂—S—CH₂—. The group that is formed by bonding Ra¹ and Ra² to each other is preferably an alkylene group having 1 to 6 carbon atoms or —O—, more preferably an alkylene group having 1 to 6 carbon atoms, still more preferably an alkylene group having 1 to 5 carbon atoms, and particularly preferably a methylene group.

In regard to Ra¹ and Ra² in General Formula (a02-1), among the above, Ra¹ and Ra² are preferably bonded to each other to form an alkylene group having 1 to 6 carbon atoms, more preferably bonded to each other to form an alkylene group having 1 to 3 carbon atoms, and still more preferably bonded to each other to form a methylene group.

In General Formula (a02-1), Ra′⁰¹ represents a halogen atom, an alkyl group having 1 to 6 carbon atoms, which may have a halogen atom, a hydroxy alkyl group having 1 to 6 carbon atoms, in which a hydroxy moiety may be protected by a protecting group and which may have a halogen atom, a carboxy group which may form a salt, or a substituted oxycarbonyl group. The halogen atom is particularly preferably a fluorine atom.

The carboxy group which may form a salt, as Ra′⁰¹, is selected from the group consisting of a carboxy group and a carboxy group forming a salt (salt of the carboxy group).

Examples of the carboxy group (salt of the carboxy group) forming a salt, as Ra′⁰¹, include an alkali metal salt, an alkaline earth metal salt, and a transition metal salt.

Examples of the substituted oxycarbonyl group as Ra′⁰¹ include: an alkoxycarbonyl group (specifically, alkyloxycarbonyl groups such as a methoxycarbonyl group, an ethoxycarbonyl group, an isopropyloxycarbonyl group, and an n-propoxycarbonyl group; and alkenyloxycharbonyl groups such as a vinyloxycarbonyl group and an arlyloxycarbonyl group) in which an alkoxy group having 1 to 4 carbon atoms is bonded with a carbonyl group; cycloalkyloxycarbonyl groups such as a cyclohexyloxycarbonyl group; and an aryloxycarbonyl group such as a phenyloxycarbonyl group.

In General Formula (a02-1), p₀ represents an integer of 0 to 8 and preferably an integer of 0 to 6 and more preferably an integer of 0 to 3. In a case where two or more Ra′⁰¹'s are present, a plurality of Ra′⁰¹'s may be the same or different from each other.

In General Formula (a02-1), q₀₁ represents an integer of 1 to 9 and preferably an integer of 1 to 5 and more preferably an integer of 1 to 2.

The constitutional unit (a02) is preferably a constitutional unit represented by General Formula (a02-11).

[chemical structure]

[In Formula (a02-11), R represents a hydrogen atom, an alkyl group having 1 to 5 carbon atoms, or a halogenated alkyl group having 1 to 5 carbon atoms. Va⁰² represents a divalent hydrocarbon group which may have a substituent. nₐ₀₂ represents an integer of 0 to 2. q₀₂ represents an integer of 1 to 7.]

[In Formula (a02-11), R, Va⁰², and nₐ₀₂ are respectively the same as R, Va⁰², and nₐ₀₂ in Formula (a02-1).

In Formula (a02-11), q₀₂ represents an integer of 1 to 7, preferably 1 or 2, and more preferably 1.

Suitable specific examples of the constitutional unit (a02) are as follows. In the following formulae, R^{α} represents a hydrogen atom, a methyl group, or a trifluoromethyl group. n_{α} represents 0 or 1.

[chemical structure]

[chemical structure]

[chemical structure]

[chemical structure]

[chemical structure]

[chemical structure]

[chemical structure]

[chemical structure]

Among the above, the constitutional unit (a02) is preferably a constitutional unit represented by any one of Formulae (a02-1a-1) to (a02-1a-18) and more preferably a constitutional unit represented by Formula (a02-1a-1).

The constitutional unit (a02) that the component (A1) has may be one kind or may be two or more kinds.

The proportion of the constitutional unit (a02) in the component (A1) is preferably 10% by mole or more and less than 50% by mole, and more preferably 20% by mole or more and 45% by mole or less, and still more preferably 30% by mole or more and 45% by mole or less, with respect to the total amount (100% by mole) of all constitutional units constituting the component (A1).

In a case where the proportion of the constitutional unit (a02) is equal to or greater than the lower limit of the preferred range described above, etching resistance can be improved. Further, in a case where the proportion of the constitutional unit (a02) is equal to or greater than the lower limit of the preferred range described above, lithography characteristics more improved due to the effects obtained by appropriately adjusting the acid diffusion length, increasing the adhesiveness of the resist film to the substrate, and appropriately adjusting the solubility during development. In addition, in a case where the proportion is equal to or lower than the upper limit of the preferred range, balance with other constitutional units can be obtained.

«Other Constitutional Units>>

The component (A1) may have other constitutional units as necessary in addition to the constitutional unit (a01) and the constitutional unit (a02) described above.

Examples of other constitutional units include: a constitutional unit (a1) (a constitutional unit corresponding to the above-described constitutional unit (a01) is excluded) containing an acid decomposable group having a polarity which is increased by an action of an acid; a constitutional unit (a2) containing a lactone-containing cyclic group, a —SO₂-containing cyclic group, or a carbonate-containing cyclic group; a constitutional unit (a3) containing a polar group-containing aliphatic hydrocarbon group; a constitutional unit (a4) containing an acid non-dissociable aliphatic cyclic group; a constitutional unit (a10) represented by General Formula (a10-1) described later; and a constitutional unit (st) derived from styrene or a derivative thereof.

In Regard to Constitutional Unit (a1):

Further, the component (A1) may have a constitutional unit (a1) (however, a constitutional unit corresponding to the constitutional unit (a01) is excluded) that contains an acid decomposable group having a polarity which is increased by an action of an acid.

Examples of the acid dissociable group in the constitutional unit (a1) include the same group as the group which has been proposed as an acid dissociable group of a base resin for a chemical amplification type resist.

Specific examples of the acid dissociable group of a base resin for a chemical amplification type resist include an “acetal-type acid dissociable group” and a “tertiary alkyloxycarbonyl-type acid dissociable group” described below.

Acetal-Type Acid Dissociable Group:

Examples of the acid dissociable group for protecting a carboxy group or a hydroxy group as a polar group include acid dissociable groups represented by General Formula (a1-r-1) (hereinafter, also referred to as then “acetal-type acid dissociable group”).

[chemical structure]

[In the formula, Ra′¹ and Ra′² represent hydrogen atoms or alkyl groups. Ra′³ represents a hydrocarbon group, and Ra′³ may be bonded to Ra′¹ or Ra′² to form a ring.]

In Formula (a1-r-1), it is preferable that at least one of Ra′¹ and Ra′² represents a hydrogen atom and more preferable that both of Ra′¹ and Ra′² represent hydrogen atoms.

In a case where Ra′¹ or Ra′² represents an alkyl group, examples of the alkyl group include the same alkyl groups as those mentioned as the substituent which may be bonded to the carbon atom at the α-position in the description on the α-substituted acrylic acid ester. Among these, an alkyl group having 1 to 5 carbon atoms is preferable. Specific examples thereof include linear or branched alkyl groups. Specific examples of the alkyl group include a methyl group, an ethyl group, a propyl group, an isopropyl group, an n-butyl group, an isobutyl group, a tert-butyl group, a pentyl group, an isopentyl group, and a neopentyl group. Among these, a methyl group or an ethyl group is more preferable, and a methyl group is particularly preferable.

In Formula (a1-r-1), examples of the hydrocarbon group as Ra′³ include a linear or branched alkyl group and a cyclic hydrocarbon group.

The linear alkyl group has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group has preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group. Among these, an isopropyl group is preferable.

In a case where Ra′³ represents a cyclic hydrocarbon group, the cyclic hydrocarbon group may be an aliphatic hydrocarbon group or an aromatic hydrocarbon group and may be a polycyclic group or a monocyclic group.

The aliphatic hydrocarbon group which is a monocyclic group is preferably a group in which one hydrogen atom has been removed from a monocycloalkane. The monocycloalkane has preferably 3 to 6 carbon atoms, and specific examples thereof include cyclopentane and cyclohexane.

The aliphatic hydrocarbon group which is a polycyclic group is preferably a group in which one hydrogen atom has been removed from a polycycloalkane. The polycycloalkane is preferably a group having 7 to 12 carbon atoms, and specific examples of thereof include adamantane, norbomane, isobornane, tricyclodecane, and tetracyclododecane.

In a case where the cyclic hydrocarbon group as Ra′³ is an aromatic hydrocarbon group, the aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring has preferably 5 to 30 carbon atoms, more preferably 5 to 20 carbon atoms, still more preferably 6 to 15 carbon atoms, and particularly preferably 6 to 12 carbon atoms. Specific examples of the aromatic ring include: aromatic hydrocarbon rings such as benzene, naphthalene, anthracene, and phenanthrene; and aromatic hetero rings in which a part of carbon atoms constituting the above-described aromatic hydrocarbon rings have been substituted with hetero atoms. Examples of the hetero atom in the aromatic hetero rings include an oxygen atom, a sulfur atom, and a nitrogen atom. Specific examples of the aromatic hetero ring include a pyridine ring and a thiophene ring.

Specific examples of the aromatic hydrocarbon group as Ra′³ include: a group in which one hydrogen atom has been removed from the above-described aromatic hydrocarbon ring or aromatic hetero ring (an aryl group or a heteroaryl group); a group in which one hydrogen atom has been removed from an aromatic compound having two or more aromatic rings (biphenyl, fluorene or the like); and a group in which one hydrogen atom of the above-described aromatic hydrocarbon ring or aromatic hetero ring has been substituted with an alkylene group (for example, arylalkyl groups such as a benzyl group, a phenethyl group, a 1-naphthylmethyl group, a 2-naphthylmethyl group, a 1-naphthylethyl group, and a 2-naphthylethyl group). The alkylene group bonded to the aromatic hydrocarbon ring or aromatic hetero ring has preferably 1 to 4 carbon atoms, more preferably 1 or 2 carbon atoms, and particularly preferably 1 carbon atom.

The cyclic hydrocarbon group in Ra′³ may have a substituent. Examples of the substituent include, —R^{P1}, —R^{P2}—O—R^{P1}, —R^{P2}—CO—R^{P1}, —R^{P2}—CO—OR^{P1}, —R^{P2}—O—CO—R^{P1}, —R^{P2}—OH, —R^{P2}—CN, and —R^{P2}—COOH (hereinafter, these substituents are also collectively referred to as “Ra^{x5}”.). Here, R^{P1} represents a monovalent chain-like saturated hydrocarbon group having 1 to 10 carbon atoms, a monovalent aliphatic cyclic saturated hydrocarbon group having 3 to 20 carbon atoms, or a monovalent aromatic hydrocarbon group having 6 to 30 carbon atoms. In addition, R^{P2} represents a single bond, a divalent chain-like saturated hydrocarbon group having 1 to 10 carbon atoms, a divalent aliphatic cyclic saturated hydrocarbon group having 3 to 20 carbon atoms, or a divalent aromatic hydrocarbon group having 6 to 30 carbon atoms. However, a part or all of the hydrogen atoms contained in the chain-like saturated hydrocarbon group, aliphatic cyclic saturated hydrocarbon group, and aromatic hydrocarbon group of R^{P1} and R^{P2} may be substituted with fluorine atoms. In the aliphatic cyclic hydrocarbon group, one or more of the above-described substituents may be included as a single kind, or one or more of the above-described substituents may be included as a plurality of kinds.

Examples of the monovalent chain-like saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms include: monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and cyclododecyl group; and polycyclic aliphatic saturated hydrocarbon groups such as a bicyclo[2.2.2]octanyl group, a tricyclo[5.2.1.02,6]decanyl group, a tricyclo [3.3.1.13,7]decanyl group, a tetracyclo[6.2.1.13,6.02,7] dodecanyl group, and an adamantyl group.

Examples of the monovalent aromatic hydrocarbon group having 6 to 30 carbon atoms include groups in which one hydrogen atom has been removed from aromatic hydrocarbon rings such as benzene, biphenyl, fluorene, naphthalene, anthracene, and phenanthrene.

In a case where Ra′³ is bonded to Ra′¹ or Ra′² to form a ring, the cyclic group is preferably a 4- to 7-membered ring, and more preferably a 4- to 6-membered ring.

Specific examples of the cyclic group include a tetrahydropyranyl group and a tetrahydrofuranyl group.

Tertiary Alkyloxycarbonyl-Type Acid Dissociable Group:

Examples of the acid dissociable group for protecting a hydroxy group as a polar group include acid dissociable groups (hereinafter, for convenience, also referred to as “tertiary alkyloxy carbonyl-type acid dissociable group”) represented by General Formula (a1-r-3).

[chemical structure]

[In the formula, Ra′⁷ to Ra′⁹ each represent an alkyl group.]

In Formula (a1-r-3), Ra′⁷ to Ra′⁹ each independently represent preferably an alkyl group having 1 to 5 carbon atoms and more preferably an alkyl group having 1 to 3 carbon atoms.

Further, the total number of carbon atoms in each alkyl group is preferably 3 to 7, more preferably 3 to 5, and most preferably 3 or 4.

The proportion of the constitutional unit (a1) in the component (A1) is preferably 5% to 40% by mole and more preferably 10% to 40% by mole, with respect to the total amount (100% by mole) of all constitutional units constituting the component (A1).

In a case where the proportion of the constitutional unit (a1) is equal to or greater than the lower limit of the preferred range described above, lithography characteristics such as sensitivity, resolution, and roughness are improved. On the other hand, in a case where the proportion is equal to or lower than the upper limit of the preferred range described above, balance with other constitutional units can be obtained, and various lithography characteristics are improved.

In Regard to Constitutional Unit (a2):

The component (A1) may further have a constitutional unit (a2) (however, a constitutional unit corresponding to the constitutional unit (a01), the constitutional unit (a02), or the constitutional unit (a1) is excluded) containing a lactone-containing cyclic group, a —SO₂-containing cyclic group, or a carbonate-containing cyclic group.

In a case where the component (A1) is used for forming a resist film, the lactone-containing cyclic group, the —SO₂-containing cyclic group, or the carbonate-containing cyclic group in the constitutional unit (a2) is effective for improving the adhesiveness of the resist film to the substrate. Further, due to having the constitutional unit (a2), lithography characteristics can be improved, for example, by the effects obtained by appropriately adjusting the acid diffusion length, increasing the adhesiveness of the resist film to the substrate, and appropriately adjusting the solubility during development.

The term “lactone-containing cyclic group” indicates a cyclic group that contains a ring (lactone ring) containing a —O—C(═O)— in the ring skeleton. In a case where the lactone ring is counted as the first ring and the group contains only the lactone ring, the group is referred to as the monocyclic group. Further, in a case where the group has other ring structures, the group is referred to as the polycyclic group regardless of the structures. The lactone-containing cyclic group may be a monocyclic group or a polycyclic group.

The lactone-containing cyclic group for the constitutional unit (a2) is not particularly limited, and any constitutional unit may be used. Specific examples thereof include groups respectively represented by General Formulae (a2-r-1) to (a2-r-7).

[chemical structure]

[In the formulae, each Ra′²¹ independently represent a hydrogen atom, an alkyl group, an alkoxy group, a halogen atom, a halogenated alkyl group, a hydroxy group, —COOR″, —OC(═O)R″, or a hydroxyalkyl group; R″ represents a hydrogen atom, an alkyl group, a lactone-containing cyclic group, a carbonate-containing cyclic group, or a —SO₂-containing cyclic group; A″ represents an oxygen atom, a sulfur atom, or an alkylene group having 1 to 5 carbon atoms, which may contain an oxygen atom (—O—) or a sulfur atom (—S—); and n′ represents an integer of 0 to 2, and m′ is 0 or 1.]

In General Formulae (a2-r-1) to (a2-r-7), the alkyl group as Ra′²¹ is preferably an alkyl group having 1 to 6 carbon atoms. The alkyl group is preferably a linear alkyl group or a branched alkyl group. Specific examples thereof include a methyl group, an ethyl group, a propyl group, an isopropyl group, an n-butyl group, an isobutyl group, a tert-butyl group, a pentyl group, an isopentyl group, a neopentyl group, and a hexyl group. Among these, a methyl group or ethyl group is preferable, and a methyl group is particularly preferable.

The alkoxy group as Ra′²¹ is preferably an alkoxy group having 1 to 6 carbon atoms. Further, the alkoxy group is preferably a linear or branched alkoxy group. Specific examples of the alkoxy group include groups formed by linking the above-described alkyl group mentioned as the alkyl group represented by Ra′²¹ to an oxygen atom (—O—).

The halogen atom as Ra′²¹ is preferably a fluorine atom.

Examples of the halogenated alkyl group as Ra′²¹ include groups in which a part or all hydrogen atoms in the above-described alkyl group as Ra′²¹ have been substituted with the above-described halogen atoms. The halogenated alkyl group is preferably a fluorinated alkyl group and particularly preferably a perfluoroalkyl group.

In —COOR″ and —OC(═O)R″ as Ra′²¹, both R′″s represent a hydrogen atom, an alkyl group, a lactone-containing cyclic group, a carbonate-containing cyclic group, or a —SO₂-containing cyclic group.

The alkyl group as R″ may be linear, branched, or cyclic, and preferably has 1 to 15 carbon atoms.

In a case where R″ represents a linear or branched alkyl group, it is preferably an alkyl group having 1 to 10 carbon atoms, more preferably an alkyl group having 1 to 5 carbon atoms, and particularly preferably a methyl group or an ethyl group.

In a case where R″ represents a cyclic alkyl group, the number of carbon atoms thereof is preferably 3 to 15, more preferably 4 to 12, and most preferably 5 to 10. Specific examples thereof include: a group in which one or more hydrogen atoms have been removed from a monocycloalkane which may or may not be substituted with a fluorine atom or a fluorinated alkyl group; and a group in which one or more hydrogen atoms have been removed from polycycloalkanes such as a bicycloalkane, a tricycloalkane, and a tetracycloalkane. More specific examples thereof include: a group in which one or more hydrogen atoms have been removed from monocycloalkanes such as cyclopentane and cyclohexane; and a group in which one or more hydrogen atoms have been removed from polycycloalkanes such as adamantane, norbomane, isobomane, tricyclodecane, and tetracyclododecane.

Examples of the lactone-containing cyclic group as R″ include the same groups as those respectively represented by General Formulae (a2-r-1) to (a2-r-7).

The carbonate-containing cyclic group as R″ has the same definition as that for the carbonate-containing cyclic group described below. Specific examples of the carbonate-containing cyclic group include groups respectively represented by General Formulae (ax3-r-1) to (ax3-r-3).

The —SO₂-containing cyclic group as R″ has the same definition as that for the —SO₂-containing cyclic group described below. Specific examples of the —SO₂-containing cyclic group include groups respectively represented by General Formulae (a5-r-1) to (a5-r-4).

The hydroxyalkyl group as Ra′²¹ has preferably 1 to 6 carbon atoms, and specific examples thereof include groups in which at least one hydrogen atom in the alkyl group as Ra′²¹ has been substituted with a hydroxy group.

In General Formulae (a2-r-2), (a2-r-3), and (a2-r-5), as the alkylene group having 1 to 5 carbon atoms as A″, a linear or branched alkylene group is preferable, and examples thereof include a methylene group, an ethylene group, an n-propylene group, and an isopropylene group. Specific examples of the alkylene group that contains an oxygen atom or a sulfur atom include groups in which —O— or —S— is interposed in the terminal of the alkylene group or between the carbon atoms of the alkylene group, and examples thereof include —O—CH₂—, —CH₂—O—CH₂—, —S—CH₂—, and —CH₂—S—CH₂—. A″ is preferably an alkylene group having 1 to 5 carbon atoms or —O—, more preferably an alkylene group having 1 to 5 carbon atoms, and most preferably a methylene group.

Specific examples of the groups respectively represented by General Formulae (a2-r-1) to (a2-r-7) are as follows.

[chemical structure]

[chemical structure]

[chemical structure]

[chemical structure]

[chemical structure]

[chemical structure]

The “—SO₂-containing cyclic group” indicates a cyclic group having a ring containing —SO₂— in the ring skeleton thereof. Specifically, the —SO₂-containing cyclic group is a cyclic group in which the sulfur atom (S) in —SO₂— forms a part of the ring skeleton of the cyclic group. In a case where the ring containing —SO₂— in the ring skeleton thereof is counted as the first ring and the group contains only the ring, the group is referred to as the monocyclic group. Further, in a case where the group has other ring structures, the group is referred to as the polycyclic group regardless of the structures. The —SO₂-containing cyclic group may be a monocyclic group or a polycyclic group. The —SO₂-containing cyclic group is particularly preferably a cyclic group containing —O—SO₂— in the ring skeleton thereof, that is, a cyclic group containing a sultone ring in which —O—S— in the —O—SO₂— group forms a part of the ring skeleton thereof.

More specific examples of the —SO₂-containing cyclic group include groups respectively represented by General Formulae (a5-r-1) to (a5-r-4).

[chemical structure]

[In the formulae, each Ra′⁵¹ independently represent a hydrogen atom, an alkyl group, an alkoxy group, a halogen atom, a halogenated alkyl group, a hydroxy group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂-containing cyclic group; A″ represents an oxygen atom, a sulfur atom, or an alkylene group having 1 to 5 carbon atoms, which may contain an oxygen atom or a sulfur atom; and n′ represents an integer of 0 to 2.]

In General Formulae (a5-r-1) and (a5-r-2), A″ is the same as A″ in General Formulae (a2-r-2), (a2-r-3) and (a2-r-5).

Examples of the alkyl group, the alkoxy group, the halogen atom, the halogenated alkyl group, —COOR″, —OC(═O)R″, and the hydroxyalkyl group, as Ra′⁵¹, include the same groups as those described above in the explanation of Ra′²¹ in General Formulae (a2-r-1) to (a2-r-7).

Specific examples of the groups respectively represented by General Formulae (a5-r-1) to (a5-r-4) are as follows. In the following formulae, “Ac” represents an acetyl group.

[chemical structure]

[chemical structure]

[chemical structure]

[chemical structure]

[chemical structure]

[chemical structure]

The “carbonate-containing cyclic group” indicates a cyclic group having a ring (a carbonate ring) containing —O—C(═O)—O— in the ring skeleton thereof. In a case where the carbonate ring is counted as the first ring and the group contains only the carbonate ring, the group is referred to as the monocyclic group. Further, in a case where the group has other ring structures, the group is referred to as the polycyclic group regardless of the structures. The carbonate-containing cyclic group may be a monocyclic group or a polycyclic group.

The carbonate ring-containing cyclic group is not particularly limited, and any group may be used. Specific examples thereof include groups respectively represented by General Formulae (ax3-r-1) to (ax3-r-3).

[chemical structure]

In the formulae, each Ra′^{x31} independently represent a hydrogen atom, an alkyl group, an alkoxy group, a halogen atom, a halogenated alkyl group, a hydroxy group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂-containing cyclic group; A″ represents an oxygen atom, a sulfur atom, or an alkylene group having 1 to 5 carbon atoms, which may contain an oxygen atom or a sulfur atom; and p′ represents an integer of 0 to 3, and q′ is 0 or 1.]

In General Formulae (ax3-r-2) and (ax3-r-3), A″ is the same as A″ in General Formulae (a2-r-2), (a2-r-3) and (a2-r-5).

Examples of the alkyl group, the alkoxy group, the halogen atom, the halogenated alkyl group, —COOR″, —OC(═O)R″, and the hydroxy alkyl group, as Ra′³¹, include the same groups as those described above in the explanation of Ra′²¹ in General Formulae (a2-r-1) to (a2-r-7).

Specific examples of the groups respectively represented by General Formulae (ax3-r-1) to (ax3-r-3) are as follows.

[chemical structure]

[chemical structure]

[chemical structure]

Among them, the constitutional unit (a2) is preferably a constitutional unit derived from the acrylic acid ester in which the hydrogen atom bonded to the carbon atom at the α-position may be substituted with a substituent.

The constitutional unit (a2) is preferably a constitutional unit represented by General Formula (a2-1).

[chemical structure]

[In the formula, R represents a hydrogen atom, an alkyl group having 1 to 5 carbon atoms, or a halogenated alkyl group having 1 to 5 carbon atoms. Ya²¹ represents a single bond or a divalent linking group. La²¹ represents —O—, —COO—, —CON(R′)—, —OCO—, —CONHCO— or —CONHCS—, and R′ represents a hydrogen atom or a methyl group. However, in a case where La²¹ represents —O—, Ya²¹ does not represent —CO—. Ra²¹ represents a lactone-containing cyclic group, a carbonate-containing cyclic group, or a —SO₂-containing cyclic group.]

In Formula (a2-1), R is the same as the above. R is preferably a hydrogen atom, an alkyl group having 1 to 5 carbon atoms, or a fluorinated alkyl group having 1 to 5 carbon atoms, and particularly preferably a hydrogen atom or a methyl group in terms of industrial availability.

In Formula (a2-1), the divalent linking group as Ya²¹ is not particularly limited, and suitable examples thereof include a divalent hydrocarbon group which may have a substituent and a divalent linking group having a hetero atom.

Divalent Hydrocarbon Group which May have Substituent:

In a case where Ya²¹ represents a divalent hydrocarbon group which may have a substituent, the hydrocarbon group may be an aliphatic hydrocarbon group or an aromatic hydrocarbon group.

Aliphatic Hydrocarbon Group as Ya²¹

The aliphatic hydrocarbon group indicates a hydrocarbon group that has no aromaticity. The aliphatic hydrocarbon group may be saturated or unsaturated. In general, the aliphatic hydrocarbon group is preferably saturated. Examples of the aliphatic hydrocarbon group include a linear or branched aliphatic hydrocarbon group, and an aliphatic hydrocarbon group containing a ring in the structure thereof.

Linear or Branched Aliphatic Hydrocarbon Group

The linear aliphatic hydrocarbon group has preferably 1 to 10 carbon atoms, more preferably 1 to 6 carbon atoms, still more preferably 1 to 4 carbon atoms, and most preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group has preferably 2 to 10 carbon atoms, more preferably 3 to 6 carbon atoms, still more preferably 3 or 4 carbon atoms, and most preferably 3 carbon atoms.

The branched aliphatic hydrocarbon group is preferably a branched alkylene group, and specific examples thereof include alkylalkylene groups; for example, alkylmethylene groups such as —CH(CH₃)—, —CH(CH₂CH₃)—, —C(CH₃)₂—, —C(CH₃)(CH₂CH₃>, —C(CH₃)(CH₂CH₂CH₃>, and —C(CH₂CH₃)₂—; alkylethylene groups such as —CH(CH₃)CH₂—, —CH(CH₃)CH(CH₃>, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. The alkyl group in the alkylalkylene group is preferably a linear alkyl group having 1 to 5 carbon atoms.

The linear or branched aliphatic hydrocarbon group may or may not have a substituent. Examples of the substituent include a fluorine atom, a fluorinated alkyl group having 1 to 5 carbon atoms, which has been substituted with a fluorine atom, and a carbonyl group.

Aliphatic Hydrocarbon Group Containing Ring in Structure Thereof

Examples of the aliphatic hydrocarbon group containing a ring in the structure thereof include a cyclic aliphatic hydrocarbon group which may have a substituent containing a hetero atom in the ring structure thereof (a group in which two hydrogen atoms have been removed from an aliphatic hydrocarbon ring), a group in which the cyclic aliphatic hydrocarbon group is bonded to the terminal of a linear or branched aliphatic hydrocarbon group, and a group in which the cyclic aliphatic hydrocarbon group is interposed in a linear or branched aliphatic hydrocarbon group. Examples of the linear or branched aliphatic hydrocarbon group include the same groups as those described above.

The cyclic aliphatic hydrocarbon group has preferably 3 to 20 carbon atoms and more preferably 3 to 12 carbon atoms.

The cyclic aliphatic hydrocarbon group may be a polycyclic group or a monocyclic group. The monocyclic alicyclic hydrocarbon group is preferably a group in which two hydrogen atoms have been removed from a monocycloalkane. The monocycloalkane has preferably 3 to 6 carbon atoms, and specific examples thereof include cyclopentane and cyclohexane. The polycyclic alicyclic hydrocarbon group is preferably a group in which two hydrogen atoms have been removed from a poly cycloalkane. The polycycloalkane is preferably a group having 7 to 12 carbon atoms, and specific examples of the polycycloalkane include adamantane, norbornane, isobornane, tricyclodecane, and tetracyclododecane.

The cyclic aliphatic hydrocarbon group may or may not have a substituent. Examples of the substituent include an alkyl group, an alkoxy group, a halogen atom, a halogenated alkyl group, a hydroxy group, and a carbonyl group.

The alkyl group as the substituent is preferably an alkyl group having 1 to 5 carbon atoms, and more preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and still more preferably a methoxy group or an ethoxy group.

The halogen atom as the substituent is preferably a fluorine atom.

Examples of the halogenated alkyl group as the substituent include groups in which a part or all hydrogen atoms in the above-described alkyl groups have been substituted with the above-described halogen atoms.

In the cyclic aliphatic hydrocarbon group, a part of carbon atoms constituting the ring structure thereof may be substituted with a substituent containing a hetero atom. The substituent containing a hetero atom is preferably —O—, —C(═O)—O—, —S—, —S(═O)₂—, or —S(═O)₂—O—.

Aromatic Hydrocarbon Group as Ya²¹

The aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring has preferably 5 to 30 carbon atoms, more preferably 5 to 20 carbon atoms, still more preferably 6 to 15 carbon atoms, and particularly preferably 6 to 12 carbon atoms. However, the number of carbon atoms in a substituent is not included in the number of carbon atoms.

Specific examples of the aromatic ring include: aromatic hydrocarbon rings such as benzene, naphthalene, anthracene, and phenanthrene; and aromatic hetero rings in which a part of carbon atoms constituting the above-described aromatic hydrocarbon rings have been substituted with hetero atoms. Examples of the hetero atom in the aromatic hetero rings include an oxygen atom, a sulfur atom, and a nitrogen atom. Specific examples of the aromatic hetero ring include a pyridine ring and a thiophene ring.

Specific examples of the aromatic hydrocarbon group include a group in which two hydrogen atoms have been removed from the above-described aromatic hydrocarbon ring or aromatic hetero ring (an arylene group or a heteroarylene group); a group in which two hydrogen atoms have been removed from an aromatic compound having two or more aromatic rings (such as biphenyl or fluorene); and a group in which one hydrogen atom of a group (an aryl group or a heteroaryl group) obtained by removing one hydrogen atom from the above-described aromatic hydrocarbon ring or aromatic hetero ring has been substituted with an alkylene group (for example, a group obtained by further removing one hydrogen atom from an aryl group in an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aryl group or the heteroaryl group has preferably 1 to 4 carbon atoms, more preferably 1 or 2 carbon atoms, and particularly preferably 1 carbon atom.

With respect to the aromatic hydrocarbon group, the hydrogen atom that the aromatic hydrocarbon group has may be substituted with a substituent. For example, the hydrogen atom bonded to the aromatic ring in the aromatic hydrocarbon group may be substituted with a substituent. Examples of substituents include an alkyl group, an alkoxy group, a halogen atom, a halogenated alkyl group, and a hydroxy group.

The alkyl group as the substituent is preferably an alkyl group having 1 to 5 carbon atoms, and more preferably a methyl group, an ethyl group, a propyl group, an n-butyl group, or a tert-butyl group.

Examples of the alkoxy group, the halogen atom, and the halogenated alkyl group, as the substituent, include those exemplified as the substituent that is substituted for a hydrogen atom that the cyclic aliphatic hydrocarbon group has.

Divalent Linking Group Containing Hetero Atom

In a case where Ya²¹ represents a divalent linking group containing a hetero atom, preferred examples of the linking group include —O—, —C(═O)—O—, —O—C(═O)—, —C(═O)—, —O—C(═O)—O— —C(═O)—NH—, —NH—, —NH—C(═NH)— (H may be substituted with a substituent such as an alkyl group, an acyl group, or the like), —S—, —S(═O)₂—, —S(═O)₂—O—, and a group represented by General Formula; —Y²¹—O—Y²²—, —Y²¹—O—, —Y²¹—C(═O)—O—, —C(═O)—O—Y²¹—, —[Y²¹—C(═O)—O]_{m″}—Y²²—, —Y²¹—O—C(═O)—Y²²— or —Y²¹—S(═O)₂—O—Y²²— [In the formulae, Y²¹ and Y²² each independently represent a divalent hydrocarbon group which may have a substituent, O represents an oxygen atom, and m″ represents an integer of 0 to 3.]

In a case where the divalent linking group containing a hetero atom is —C(═O)—NH—, —C(═O)—NH—C(═O)—, —NH—, or —NH—C(═NH)—, H in these group may be substituted with a substituent such as an alkyl group, and an acyl group. The substituent (an alkyl group, an acyl group, or the like) has preferably 1 to 10 carbon atoms, more preferably 1 to 8 carbon atoms, and particularly preferably 1 to 5 carbon atoms.

In General Formula —Y²¹—O—Y²²—, —Y²¹—O—, —Y²¹—C(═O)—O—, —C(═O)—O—Y²¹—, —[Y²¹—C(═O)—O]_{m″}—Y²²—, —Y²¹—O—C(═O)—Y²²—, or —Y²¹—S(═O)₂—O—Y²²—, Y²¹ and Y²² each independently represent a divalent hydrocarbon group which may have a substituent. Examples of the divalent hydrocarbon group include the same groups as those (divalent hydrocarbon groups which may have a substituent) mentioned in the description of the above-described divalent linking group as Ya²¹.

Y²¹ is preferably a linear aliphatic hydrocarbon group, more preferably a linear alkylene group, still more preferably a linear alkylene group having 1 to 5 carbon atoms, and particularly preferably a methylene group or an ethylene group.

Y²² is preferably a linear or branched aliphatic hydrocarbon group and more preferably a methylene group, an ethylene group, or an alkylmethylene group. The alkyl group in the alkylmethylene group is preferably a linear alkyl group having 1 to 5 carbon atoms, more preferably a linear alkyl group having 1 to 3 carbon atoms, and most preferably a methyl group.

In the group represented by Formula —[Y²¹—C(═O)—O]_{m″}—Y²²—, m″ represents an integer of 0 to 3, preferably an integer of 0 to 2, more preferably 0 or 1, and particularly preferably 1. In other words, the group represented by Formula —[Y²¹—C(═O)—O]_{m″}—Y²²— is particularly preferably a group represented by Formula —Y²¹—C(═O)—O—Y²²—. Among them, a group represented by Formula —(CH₂)_{a′}—C(═O)—O—(CH₂)_{b′}— is preferable. In the formula, a′ represents an integer of 1 to 10, preferably an integer of 1 to 8, more preferably an integer of 1 to 5, still more preferably 1 or 2, and most preferably 1. b′ represents an integer of 1 to 10, preferably an integer of 1 to 8, more preferably an integer of 1 to 5, still more preferably 1 or 2, and most preferably 1.

Among the above, Ya²¹ is preferably a single bond, an ester bond [—C(═O)—O—], an ether bond (—O—), a linear or branched alkylene group, or a combination thereof.

In Formula (a2-1), Ra²¹ represents a lactone-containing cyclic group, a —SO₂— containing cyclic group, or a carbonate-containing cyclic group.

Suitable examples of the lactone-containing cyclic group, the —SO₂-containing cyclic group, and the carbonate-containing cyclic group, as Ra²¹, respectively include groups respectively represented by General Formulae (a2-r-1) to (a2-r-7), groups respectively represented by General Formulae (a5-r-1) to (a5-r-4), and groups respectively represented by General Formulae (ax3-r-1) to (ax3-r-3) described above.

Among them, a lactone-containing cyclic group or a —SO₂-containing cyclic group is preferable, and groups respectively represented by General Formula (a2-r-1), (a2-r-2), (a2-r-6), or (a5-r-1) are more preferable. Specifically, groups respectively represented by any one of Chemical Formulae (r-1c-1-1) to (r-1c-1-7), (r-1c-2-1) to (r-1c-2-18), (r-1c-6-1), (r-s1-1-1), and (r-s1-1-18) are more preferable.

The constitutional unit (a2) which the component (A1) has may be one kind or may be two or more kinds.

In a case where the component (A1) has the constitutional unit (a2), the proportion of the constitutional unit (a2) is preferably 5% to 40% by mole, more preferably 10% to 40% by mole, still more preferably 20% to 40% by mole, and particularly preferably 30% to 40% by mole, with respect to the total amount (100% by mole) of all constitutional units constituting the component (A1).

In a case where the proportion of the constitutional unit (a2) is equal to or greater than the lower limit of the above-described preferred range, the effect obtained by allowing the component (A1) to contain the constitutional unit (a2) can be sufficiently achieved by the effect described above. In a case where the proportion of the constitutional unit (a2) is equal to or lower than the upper limit of the above-described preferred range, balance with other constitutional units can be obtained, and various lithography characteristics are improved.

In Regard to Constitutional Unit (a3):

The component (A1) may further have a constitutional unit (a3) (however, a constitutional unit corresponding to the constitutional unit (a01), the constitutional unit (a02), or the constitutional unit (a1) is excluded) or the constitutional unit (a2) is excluded) containing an polar group-containing aliphatic hydrocarbon group. In a case where the component (A1) has the constitutional unit (a3), the hydrophilicity of the component (A) is increased, which contributes to an improvement in resolution. Further, the acid diffusion length can be appropriately adjusted.

Examples of the polar group include a hydroxy group, a cyano group, a carboxy group, or a hydroxyalkyl group in which a part of hydrogen atoms of the alkyl group have been substituted with fluorine atoms. Among these, a hydroxy group is particularly preferable.

Examples of the aliphatic hydrocarbon group include a linear or branched hydrocarbon group (preferably alkylene group) having 1 to 10 carbon atoms, and a cyclic aliphatic hydrocarbon group (cyclic group). The cyclic group may be a monocyclic group or a polycyclic group. For example, these cyclic groups can be properly selected from a large number of groups that have been proposed for a resin for a resist composition for an ArF excimer laser.

In a case where the cyclic group is a monocyclic group, the monocyclic group more preferably has 3 to 10 carbon atoms. Among them, constitutional units derived from the acrylic acid ester that includes an aliphatic monocyclic group containing a hydroxy group, cyano group, carboxy group, or a hydroxyalkyl group in which a part of hydrogen atoms of the alkyl group have been substituted with fluorine atoms are more preferable. Examples of the monocyclic group include groups in which two or more hydrogen atoms have been removed from a monocycloalkane. Specific examples of the monocyclic group include groups in which two or more hydrogen atoms have been removed from monocycloalkanes such as cyclopentane, cyclohexane, and cyclooctane. Among these monocyclic groups, a group in which two or more hydrogen atoms have been removed from cyclopentane or a group in which two or more hydrogen atoms have been removed from cyclohexane are industrially preferable.

In a case where the cyclic group is a polycyclic group, the polycyclic group more preferably has 7 to 30 carbon atoms. Among them, constitutional units derived from the acrylic acid ester that includes an aliphatic polycyclic group containing a hydroxy group, cyano group, carboxy group, or a hydroxyalkyl group in which a part of hydrogen atoms of the alkyl group have been substituted with fluorine atoms are more preferable. Examples of the polycyclic group include groups in which two or more hydrogen atoms have been removed from a bicycloalkane, a tricycloalkane, a tetracycloalkane, or the like. Specific examples thereof include groups in which two or more hydrogen atoms have been removed from polycycloalkanes such as adamantane, norbomane, isobomane, tricyclodecane, and tetracyclododecane. Among these polycyclic groups, a group in which two or more hydrogen atoms have been removed from adamantane, a group in which two or more hydrogen atoms have been removed from norbomane, and a group in which two or more hydrogen atoms have been removed from tetracyclododecane are preferred industrially.

The constitutional unit (a3) is not particularly limited, and any constitutional unit may be used as long as the constitutional unit contains a polar group-containing aliphatic hydrocarbon group.

The constitutional unit (a3) is preferably a constitutional unit containing a polar group-containing aliphatic hydrocarbon group, which is a constitutional unit derived from the acrylic acid ester in which the hydrogen atom bonded to the carbon atom at the α-position may be substituted with a substituent.

In a case where the hydrocarbon group in the polar group-containing aliphatic hydrocarbon group is a linear or branched hydrocarbon group having 1 to 10 carbon atoms, the constitutional unit (a3) is preferably a constitutional unit derived from a hydroxy ethyl ester of acrylic acid.

Further, examples of the constitutional unit (a3) include, as a preferred constitutional unit: in a case where the hydrocarbon group in the polar group-containing aliphatic hydrocarbon group is a polycyclic group, a constitutional unit represented by Formula (a3-1), a constitutional unit represented by Formula (a3-2), and a constitutional unit represented by Formula (a3-3); and in a case where the hydrocarbon group is a monocyclic group, a constitutional unit represented by Formula (a3-4).

[chemical structure]

[In the formulae, R is the same as the above, j represents an integer of 1 to 3, k represents an integer of 1 to 3, t′ represents an integer of 1 to 3,1 represents an integer of 0 to 5, and s represents an integer of 1 to 3.]

In Formula (a3-1), j represents preferably 1 or 2 and more preferably 1. In a case where j represents 2, it is preferable that the hydroxy groups are bonded to the 3rd and 5th positions of the adamantyl group. In a case where j represents 1, it is preferable that the hydroxy group is bonded to the 3-position of the adamantyl group. It is preferable that j represents 1, and it is particularly preferable that the hydroxy group is bonded to the 3-position of the adamantyl group.

In Formula (a3-2), k represents preferably 1. The cyano group is preferably bonded to the 5- or 6-position of the norbornyl group.

In Formula (a3-3), it is preferable that t′ represents 1. It is preferable that 1 represents 1. It is preferable that s represents 1. Further, it is preferable that a 2-norbornyl group or 3-norbornyl group is bonded to the terminal of the carboxy group of the acrylic acid. It is preferable that the fluorinated alkyl alcohol is bonded to the 5- or 6-position of the norbornyl group.

In Formula (a3-4), it is preferable that t′ represents 1 or 2. It is preferable that 1 represents 0 or 1. It is preferable that s represents 1. It is preferable that the fluorinated alkyl alcohol is bonded to the 3- or 5-position of the cyclohexyl group.

The constitutional unit (a3) which the component (A1) has may be one kind or may be two or more kinds.

In a case where the component (A1) has the constitutional unit (a3), the proportion of the constitutional unit (a3) is preferably 1% to 30% by mole, more preferably 2% to 25% by mole, and still more preferably 5% to 20% by mole, with respect to the total amount (100% by mole) of all constitutional units constituting the component (A1).

In a case where the proportion of the constitutional unit (a3) is equal to or greater than the lower limit of the above-described preferred range, the effect obtained by allowing the component (A1) to contain the constitutional unit (a3) can be sufficiently achieved by the effect described above. In a case where the proportion of the constitutional unit (a3)) is equal to or lower than the upper limit of the above-described preferred range, balance with other constitutional units can be obtained, and various lithography characteristics are improved.

In Regard to Constitutional Unit (a4):

The component (A1) may further have a constitutional unit (a4) containing an acid non-dissociable aliphatic cyclic group.

In a case where the component (A1) has the constitutional unit (a4), the dry etching resistance of the formed resist pattern is improved. Further, the hydrophobicity of the component (A) is improved. The improvement in hydrophobicity contributes to the improvement in resolution, resist pattern shape, and the like, particularly in the case of a solvent developing process. The “acid non-dissociable cyclic group” in the constitutional unit (a4) is a cyclic group that remains in the constitutional unit without being dissociated even when an acid acts in a case where the acid is generated in the resist composition by exposure (for example, in a case where an acid is generated from the constitutional unit generating an acid upon exposure or the component (B)).

The constitutional unit (a4) is preferably, for example, a constitutional unit derived from the acrylic acid ester containing an acid non-dissociable aliphatic cyclic group. As the cyclic group, a large number of cyclic groups conventionally known as the cyclic groups which are used as a resin component of a resist composition for an ArF excimer laser, a KrF excimer laser (preferably an ArF excimer laser), or the like can be used.

The cyclic group is preferably at least one selected from a tricyclodecyl group, an adamantyl group, a tetracyclododecyl group, an isobornyl group, and a norbornyl group, from the viewpoint of industrial availability. These polycyclic groups may have, as a substituent, a linear or branched alkyl group having 1 to 5 carbon atoms.

Specific examples of the constitutional unit (a4) include constitutional units respectively represented by General Formulae (a4-1) to (a4-7).

[chemical structure]

[chemical structure]

[In the formula, R^{α} is the same as the above.]

The constitutional unit (a4) which the component (A1) has may be one kind or may be two or more kinds.

In a case where the component (A1) has the constitutional unit (a4), the proportion of the constitutional unit (a4) is preferably 1% to 40% by mole and more preferably 5% to 20% by mole, with respect to the total amount (100% by mole) of all constitutional units constituting the component (A1).

In a case where the proportion of the constitutional unit (a4) is equal to or greater than the lower limit of the preferred range, the effect obtained by allowing the component (A1) to contain the constitutional unit (a4) can be sufficiently achieved. In a case where the proportion of the constitutional unit (a4) is equal to or lower than the upper limit of the preferred range, the balance with other constitutional units is obtained easily.

In Regard to Constitutional Unit (a10):

The constitutional unit (a10) is a constitutional unit represented by General Formula (a10-1).

[chemical structure]

[In the formula, R represents a hydrogen atom, an alkyl group having 1 to 5 carbon atoms, or a halogenated alkyl group having 1 to 5 carbon atoms. Ya^{x1} represents a single bond or a divalent linking group. Wa^{x1} represents an aromatic hydrocarbon group which may have a substituent, nₐₓ₁ represents an integer of 1 or more.]

In Formula (a10-1), R represents a hydrogen atom, an alkyl group having 1 to 5 carbon atoms, or a halogenated alkyl group having 1 to 5 carbon atoms.

The alkyl group having 1 to 5 carbon atoms as R is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group.

The halogenated alkyl group having 1 to 5 carbon atoms as R is a group in which a part or all hydrogen atoms of the above-described alkyl group having 1 to 5 carbon atoms have been substituted with halogen atoms. Examples of the halogen atom include a fluorine atom, a chlorine atom, a bromine atom, and an iodine atom, and a fluorine atom is particularly preferable.

R is preferably a hydrogen atom, an alkyl group having 1 to 5 carbon atoms, or a fluorinated alkyl group having 1 to 5 carbon atoms, more preferably a hydrogen atom, a methyl group, or trifluoromethyl group, still more preferably a hydrogen atom or a methyl group, and particularly preferably a methyl group, in terms of industrial availability.

In Formula (a10-1), Ya^{x1} represents a single bond or a divalent linking group.

In the chemical formulae described above, the divalent linking group as Ya^{x1} is not particularly limited, and examples thereof include, as a suitable linking group, a divalent hydrocarbon group which may have a substituent and a divalent linking group having a hetero atom. Specific examples thereof include the same group as the divalent hydrocarbon group in Va⁰¹ in Formula (a01-1). Among them, Ya^{x1} is preferably a single bond, an ester bond [—C(═O)—O—, —O—C(═O)—], an ether bond (—O—), a linear or branched alkylene group, or a combination thereof, and more preferably a single bond or an ester bond [—C(═O)—O—, —O—C(═O)—].

In Formula (a10-1), Wa^{x1} represents an aromatic hydrocarbon group which may have a substituent.

Examples of the aromatic hydrocarbon group as Wa^{x1}, which may have a substituent, include groups in which (nₐₓ₁+1) hydrogen atoms have been removed from an aromatic ring which may have a substituent. The aromatic ring is not particularly limited as long as it is a cyclic conjugated system having (4n+2) π electrons and may be monocyclic or polycyclic. The aromatic ring has preferably 5 to 30 carbon atoms, more preferably 5 to 20 carbon atoms, still more preferably 6 to 15 carbon atoms, and particularly preferably 6 to 12 carbon atoms. Specific examples of the aromatic ring include aromatic hydrocarbon rings such as benzene, naphthalene, anthracene, and phenanthrene; and aromatic hetero rings in which a part of carbon atoms constituting the above-described aromatic hydrocarbon rings have been substituted with hetero atoms. Examples of the hetero atom in the aromatic hetero rings include an oxygen atom, a sulfur atom, and a nitrogen atom. Specific examples of the aromatic hetero ring include a pyridine ring and a thiophene ring.

Examples of the aromatic hydrocarbon group as Wa^{x1} also include groups in which (nₐₓ₁+1) hydrogen atoms have been removed from an aromatic compound (for example, biphenyl and fluorene) containing an aromatic ring which may have two or more substituents.

Among the above, Wa^{x1} is preferably a group in which (nₐₓ₁+1) hydrogen atoms have been removed from benzene, naphthalene, anthracene, or biphenyl, more preferably a group in which (nₐₓ₁+1) hydrogen atoms have been removed from benzene or naphthalene, and still more preferably a group in which (nₐₓ₁+1) hydrogen atoms have been removed from benzene.

The aromatic hydrocarbon group as Wa^{x1} may or may not have a substituent. Examples of the substituent include an alkyl group, an alkoxy group, a halogen atom, and a halogenated alkyl group. Examples of the alkyl group, the alkoxy group, the halogen atom, and the halogenated alkyl group, as the substituent, include the same groups as those described as the substituent for the cyclic aliphatic hydrocarbon group as Ya^{x1}. The substituent is preferably a linear or branched alkyl group having 1 to 5 carbon atoms, more preferably a linear or branched alkyl group having 1 to 3 carbon atoms, still more preferably an ethyl group or a methyl group, and particularly preferably a methyl group. The aromatic hydrocarbon group as Wa^{x1} preferably has no substituent.

In the Formula (a10-1), nₐₓ₁ represents an integer of 1 or more, preferably an integer of 1 to 10, more preferably an integer of 1 to 5, still more preferably 1, 2, or 3, and particularly preferably 1 or 2.

Specific examples of the constitutional unit (a10) represented by Formula (a10-1) are as follows.

In the following formulae, R″ represents a hydrogen atom, a methyl group, or a trifluoromethyl group.

[chemical structure]

[chemical structure]

[chemical structure]

[chemical structure]

[chemical structure]

The constitutional unit (a10) which the component (A1) has may be one kind or may be two or more kinds.

In a case where the component (A1) has the constitutional unit (a10), the proportion of the constitutional unit (a10) in the component (A1) is preferably 5% to 40% by mole, more preferably 10% to 30% by mole, with respect to the total amount (100% by mole) of all constitutional units constituting the component (A1).

In a case where the proportion of the constitutional unit (a10) is equal to or greater than the lower limit, the sensitivity can be more easily increased. On the other hand, in a case where the proportion of the constitutional unit (a10) is equal to or lower than the upper limit, balance with other constitutional units is obtained easily.

In Regard to Constitutional Unit (St):

The constitutional unit (st) is a constitutional unit derived from styrene or a styrene derivative. A “constitutional unit derived from styrene” means a constitutional unit that is formed by the cleavage of an ethylenic double bond of styrene. A “constitutional unit derived from a styrene derivative” means a constitutional unit (however, a constitutional unit corresponding to the constitutional unit (a10) is excluded) formed by the cleavage of an ethylenic double bond of a styrene derivative.

The “styrene derivative” means a compound in which at least a part of hydrogen atoms of styrene are substituted with a substituent. Examples of the styrene derivative include a derivative in which the hydrogen atom at the α-position of styrene is substituted with a substituent, a derivative in which one or more hydrogen atoms of the benzene ring of styrene are substituted with a substituent, and a derivative in which the hydrogen atom at the α-position of styrene and one or more hydrogen atoms of the benzene ring are substituted with a substituent.

Examples of the substituent that is substituted for the hydrogen atom at the α-position of styrene include an alkyl group having 1 to 5 carbon atoms and a halogenated alkyl group having 1 to 5 carbon atoms.

The alkyl group having 1 to 5 carbon atoms is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group.

The halogenated alkyl group having 1 to 5 carbon atoms is a group in which a part or all hydrogen atoms in the alkyl group having 1 to 5 carbon atoms have been substituted with halogen atoms. Examples of the halogen atom include a fluorine atom, a chlorine atom, a bromine atom, and an iodine atom, and a fluorine atom is particularly preferable. The substituent that is substituted for the hydrogen atom at the α-position of styrene is preferably an alkyl group having 1 to 5 carbon atoms or a fluorinated alkyl group having 1 to 5 carbon atoms, more preferably an alkyl group having 1 to 3 carbon atoms or a fluorinated alkyl group having 1 to 3 carbon atoms, and still more preferably a methyl group from the viewpoint of industrial availability.

Examples of the substituent that is substituted for the hydrogen atom of the benzene ring of styrene include an alkyl group, an alkoxy group, a halogen atom, and a halogenated alkyl group.

The alkyl group as the substituent is preferably an alkyl group having 1 to 5 carbon atoms, and more preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and still more preferably a methoxy group or an ethoxy group.

Examples of the halogen atom as the substituent include a fluorine atom, a chlorine atom, a bromine atom, and an iodine atom, and a fluorine atom is preferable.

Examples of the halogenated alkyl group as the substituent include groups in which a part or all hydrogen atoms in the above-described alkyl groups have been substituted with the above-described halogen atoms.

The substituent that is substituted for the hydrogen atom of the benzene ring of styrene, an alkyl group having 1 to 5 carbon atoms is preferable, a methyl group or an ethyl group is more preferable, and a methyl group is still more preferable.

The constitutional unit (st) is preferably a constitutional unit derived from styrene or a constitutional unit derived from a styrene derivative in which the hydrogen atom at the α-position of styrene is substituted with an alkyl group having 1 to 5 carbon atoms or a halogenated alkyl group having 1 to 5 carbon atoms, more preferably a constitutional unit derived from styrene, or a constitutional unit derived from a styrene derivative in which the hydrogen atom at the α-position of styrene is substituted with a methyl group, and still more preferably a constitutional unit derived from styrene.

The constitutional unit (st) which the component (A1) has may be one kind or may be two or more kinds.

In a case where the component (A1) has the constitutional unit (st), the proportion of the constitutional unit (st) is preferably 1% to 30% by mole and more preferably 3% to 20% by mole, with respect to the total amount (100% by mole) of all constitutional units constituting the component (A1).

The component (A1) contained in the resist composition may be used alone or in a combination of two or more kinds thereof.

In the resist composition of the present embodiment, as the component (A1), a polymer compound having a repeated structure of the constitutional unit (a01) and the constitutional unit (a02).

An example of the preferred component (A1) contains a polymer compound consisting of a repeated structure of the constitutional unit (a01) and a constitutional unit (a02).

In this case, the proportion of the constitutional unit (a01) in the polymer compound is more than 50% by mole and 70% by mole or less and is preferably 52% by mole or more and 70% by mole or less and more preferably 55% by mole or more and 70% by mole or less, with respect to the total amount (100% by mole) of all constitutional units constituting the polymer compound.

In addition, the proportion of the constitutional unit (a02) in the polymer compound is 30% by mole or more and less than 50% by mole and is preferably 30% by mole or more and 48% by mole or less and more preferably 30% by mole or more and 45% by mole or less, with respect to the total amount (100% by mole) of all constitutional units constituting the polymer compound.

The component (A1) can be produced by dissolving, in a polymerization solvent, each monomer from which the constitutional unit is derived, adding thereto a radical polymerization initiator such as azobisisobutyronitrile (AIBN) or dimethyl azobisisobutyrate (for example, V-601) to perform polymerization.

Alternatively, the component (A1) can be produced by dissolving, in a polymerization solvent, a monomer from which the constitutional unit (a01) is derived and a monomer from which the constitutional unit (a02) is derived, and adding thereto a radical polymerization initiator such as that described above to perform polymerization, and then performing a deprotection reaction.

Further, a —C(CF₃)₂—OH group may be introduced into the terminal of the component (A1) during the polymerization using in combination with a chain transfer agent such as HS—CH₂—CH₂—CH₂—C(CF₃)₂—OH. As described above, a copolymer into which a hydroxyalkyl group, formed by substitution of a part of hydrogen atoms in the alkyl group with fluorine atoms, has been introduced is effective for reducing development defects and reducing line edge roughness (LER: uneven irregularities of a line side wall).

The weight-average molecular weight (Mw) (based on the polystyrene-equivalent value determined by gel permeation chromatography (GPC)) of the component (A1), which is not particularly limited, is preferably 1,000 to 50,000, more preferably 2,000 to 30,000, and still more preferably 3,000 to 20,000. In a case where Mw of the component (A1) is equal to or lower than the upper limit of this preferred range, the resist composition exhibits a solubility in a solvent for a resist, which is enough for using the resist composition as a resist composition. On the other hand, in a case where Mw of the component (A1) is equal to or greater than the lower limit of this preferred range, dry etching resistance and the cross-sectional shape of the resist pattern become excellent.

Further, the polydispersity (Mw/Mn) of the component (A1) is not particularly limited but is preferably 1.0 to 4.0, more preferably 1.0 to 3.0, and particularly preferably 1.0 to 2.0. Mn represents the number average molecular weight.

In Regard to Component (A2)

In the resist composition of the present embodiment, a base material component (hereinafter, referred to as “component (A2)”) exhibiting changed solubility in a developing solution under action of acid, which does not correspond to the component (A1), may be used in combination as the component (A).

The component (A2) is not particularly limited and may be freely selected and used from a large number of conventionally known base material components for the chemical amplification type resist composition.

As the component (A2), a polymer compound or a low molecular compound may be used alone or in a combination of two or more kinds thereof.

The proportion of the component (A1) in the component (A) is preferably 25% by mass or more, more preferably 50% by mass or more, and still more preferably 75% by mass or more, and may be 100% by mass, with respect to the total mass of the component (A). In a case where the proportion is 25% by mass or more, a resist pattern having various excellent lithography characteristics, such as high sensitivity, improvement in resolution or roughness can be easily formed.

The content of the component (A) in the resist composition of the present embodiment may be adjusted depending on the resist film thickness to be formed and the like.

<Other Components>

The resist composition of the present embodiment may further contain other components in addition to the component (A) described above. Examples of the other components include a component (B), a component (D), a component (E), a component (F), and a component (S), which are described below.

“Acid Generator Component (B)”

The resist composition of the present embodiment may further contain an acid generator component (B) (hereinafter, referred to as “component (B)”) generating an acid upon exposure, in addition to the component (A).

The component (B) is not particularly limited, and those which have been proposed as an acid generator for a chemical amplification type resist composition in the related art can be used.

Examples of the acid generator are numerous and include onium salt-based acid generators such as iodonium salts and sulfonium salts; oxime sulfonate-based acid generators; diazomethane-based acid generators such as bisalkyl or bisaryl sulfonyl diazomethanes and poly(bis-sulfonyl)diazomethanes; nitrobenzylsulfonate-based acid generators; iminosulfonate-based acid generators; and disulfone-based acid generators.

Examples of the onium salt-based acid generator include a compound represented by General Formula (b-1) (hereinafter, also referred to as “component (b-1)”), a compound represented by General Formula (b-2) (hereinafter, also referred to as “component (b-2)”), and a compound represented by General Formula (b-3) (hereinafter, also referred to as “component (b-3)”).

[chemical structure]

[In formulae, R¹⁰¹ and R¹⁰⁴ to R¹⁰⁸ each independently represent a cyclic group which may have a substituent, a chain-like alkyl group which may have a substituent, or a chain-like alkenyl group which may have a substituent. R¹⁰⁴ and R¹⁰⁵ may be bonded to each other to form a ring structure. R¹⁰² represents a fluorinated alkyl group having 1 to 5 carbon atoms or a fluorine atom. Y¹⁰¹ represents a divalent linking group containing an oxygen atom or a single bond. V¹⁰¹ to V¹⁰³ each independently represent a single bond, an alkylene group, or a fluorinated alkylene group. L¹⁰¹ and L¹⁰² each independently represent a single bond or an oxygen atom. L¹⁰³ to L¹⁰⁵ each independently represent a single bond, —CO—, or —SO₂—. m represents an integer of 1 or more, and M′^{m+} represents an m-valent onium cation.]

{Anion Moiety}

Anion in Component (b-1)

In Formula (b-1), R¹⁰¹ represents a cyclic group which may have a substituent, a chain-like alkyl group which may have a substituent, or a chain-like alkenyl group which may have a substituent.

Cyclic Group which May have Substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. The aliphatic hydrocarbon group may be saturated or unsaturated. In general, the aliphatic hydrocarbon group is preferably saturated.

The aromatic hydrocarbon group as R¹⁰¹ is a hydrocarbon group having an aromatic ring. The aromatic hydrocarbon group has preferably 3 to 30 carbon atoms, more preferably 5 to 30, still more preferably 5 to 20, particularly preferably 6 to 15, and most preferably 6 to 10. Here, the number of carbon atoms in a substituent is not included in the number of carbon atoms.

Specific examples of the aromatic ring which the aromatic hydrocarbon group has as R¹⁰¹ include benzene, fluorene, naphthalene, anthracene, phenanthrene, biphenyl, and an aromatic hetero ring in which a part of carbon atoms constituting any of these aromatic rings have been substituted with hetero atoms. Examples of the hetero atom in the aromatic hetero rings include an oxygen atom, a sulfur atom, and a nitrogen atom.

Specific examples of the aromatic hydrocarbon group as R¹⁰¹ include a group in which one hydrogen atom has been removed from the above-described aromatic ring (an aryl group, for example, a phenyl group and a naphthyl group) and a group in which one hydrogen atom in the aromatic ring has been substituted with an alkylene group (for example, arylalkyl groups such as a benzyl group, a phenethyl group, a 1-naphthylmethyl group, a 2-naphthylmethyl group, 1-naphthylethyl group, and a 2-naphthylethyl group). The alkylene group (an alkyl chain in the arylalkyl group) has preferably 1 to 4 carbon atoms, more preferably 1 or 2 carbon atoms, and particularly preferably 1 carbon atom.

Examples of the cyclic aliphatic hydrocarbon group as R¹⁰¹ include aliphatic hydrocarbon groups containing a ring in the structure thereof.

Examples of the aliphatic hydrocarbon group containing a ring in the structure thereof include an alicyclic hydrocarbon group (a group in which one hydrogen atom has been removed from an aliphatic hydrocarbon ring), a group in which the alicyclic hydrocarbon group is bonded to the terminal of a linear or branched aliphatic hydrocarbon group, and a group in which the alicyclic hydrocarbon group is interposed in a linear or branched aliphatic hydrocarbon group.

The alicyclic hydrocarbon group has preferably 3 to 20 carbon atoms and more preferably 3 to 12 carbon atoms.

The alicyclic hydrocarbon group may be a polycyclic group or a monocyclic group. The monocyclic alicyclic hydrocarbon group is preferably a group in which one or more hydrogen atoms have been removed from a monocycloalkane. The monocycloalkane has preferably 3 to 6 carbon atoms, and specific examples thereof include cyclopentane and cyclohexane. The polycyclic alicyclic hydrocarbon group is preferably a group in which one or more hydrogen atoms have been removed from a polycycloalkane, and the number of carbon atoms of the polycycloalkane is preferably 7 to 30. Among them, the polycycloalkane is more preferably polycycloalkanes having a crosslinked ring-based polycyclic skeleton, such as adamantane, norbomane, isobornane, tricyclodecane, and tetracyclododecane, and polycycloalkanes having a condensed ring-based polycyclic skeleton, such as a cyclic group having a steroid skeleton.

Among them, the cyclic aliphatic hydrocarbon group as R¹⁰¹ is preferably a group in which one or more hydrogen atoms have been removed from a monocycloalkane or a polycycloalkane, more preferably a group in which one hydrogen atom has been removed from a polycycloalkane, particularly preferably an adamantyl group or a norbomyl group, and most preferably an adamantyl group.

The linear aliphatic hydrocarbon group which may be bonded to the alicyclic hydrocarbon group has preferably 1 to 10 carbon atoms, more preferably 1 to 6 carbon atoms, still more preferably 1 to 4 carbon atoms, and most preferably 1 to 3 carbon atoms. The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group which may be bonded to the alicyclic hydrocarbon group has preferably 2 to 10 carbon atoms, more preferably 3 to 6 carbon atoms, still more preferably 3 or 4 carbon atoms, and most preferably 3 carbon atoms.

The branched aliphatic hydrocarbon group is preferably a branched alkylene group, and specific examples thereof include alkylalkylene groups; for example, alkylmethylene groups such as —CH(CH₃>, —CH(CH₂CH₃>, —C(CH₃)₂—, —C(CH₃)(CH₂CH₃>, —C(CH₃)(CH₂CH₂CH₃)—, and —C(CH₂CH₃)₂—; alkylethylene groups such as —CH(CH₃)CH₂—, —CH(CH₃)CH(CH₃>, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. The alkyl group in the alkylalkylene group is preferably a linear alkyl group having 1 to 5 carbon atoms.

The cyclic hydrocarbon group as R¹⁰¹ may contain a hetero atom like a hetero ring or the like. Specific examples thereof include lactone-containing cyclic groups respectively represented by General Formulae (a2-r-1) to (a2-r-7), —SO₂-containing cyclic groups respectively represented by General Formulae (a5-r-1) to (a5-r-4), and other heterocyclic groups respectively represented by Chemical Formulae (r-hr-1) to (r-hr-16). In the formulae, * represents a bonding site that binds to Y¹⁰¹ in Formula (b-1).

[chemical structure]

[chemical structure]

Examples of the substituent for the cyclic group as R¹⁰¹ include an alkyl group, an alkoxy group, a halogen atom, a halogenated alkyl group, a hydroxy group, a carbonyl group, and a nitro group. The alkyl group as the substituent is preferably an alkyl group having 1 to 5 carbon atoms, and a methyl group, an ethyl group, a propyl group, an n-butyl group, or a tert-butyl group is most preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

Examples of the halogen atom as the substituent include a fluorine atom, a chlorine atom, a bromine atom, and an iodine atom, and a fluorine atom is preferable.

Examples of the above-described halogenated alkyl group as the substituent include groups in which a part or all hydrogen atoms in an alkyl group having 1 to 5 carbon atoms such as a methyl group, an ethyl group, a propyl group, an n-butyl group, or a tert-butyl group have been substituted with the above-described halogen atoms.

The carbonyl group as the substituent is a group that is substituted for a methylene group (—CH₂—) constituting the cyclic hydrocarbon group.

The cyclic hydrocarbon group as R¹⁰¹ may be a condensed ring type group containing a condensed ring in which an aliphatic hydrocarbon ring and an aromatic ring are condensed. Examples of the condensed ring include condensed rings in which one or more aromatic rings are condensed to a polycycloalkane having a crosslinked ring-based polycyclic skeleton. Specific examples of the crosslinked ring-based polycycloalkane include bicycloalkanes such as bicyclo[2.2.1]heptane (norbomane) and bicyclo[2.2.2]octane. The condensed ring type group is preferably a group containing a condensed ring in which two or three aromatic rings are condensed to a bicycloalkane and more preferably a group containing a condensed ring in which two or three aromatic rings are condensed to bicyclo[2.2.2]octane. Specific examples of the condensed ring type group as R¹⁰¹ include those represented by Formulae (r-br-1) to (r-br-2). In the formulae, * represents a bonding site that binds to Y¹⁰¹ in Formula (b-1).

[chemical structure]

Examples of the substituent which the condensed ring type group as R¹⁰¹ may have include an alkyl group, an alkoxy group, a halogen atom, a halogenated alkyl group, a hydroxy group, a carbonyl group, a nitro group, an aromatic hydrocarbon group, and an alicyclic hydrocarbon group.

Examples of the alkyl group, the alkoxy group, the halogen atom, and the halogenated alkyl group, as the substituent for the condensed ring type group, include the same groups as those described as the substituent for the cyclic group as R¹⁰¹.

Examples of the aromatic hydrocarbon group as the substituent for the condensed ring type group include a group in which one hydrogen atom has been removed from the above-described aromatic ring (an aryl group, for example, a phenyl group and a naphthyl group), a group in which one hydrogen atom in the aromatic ring has been substituted with an alkylene group (for example, arylalkyl groups such as a benzyl group, a phenethyl group, a 1-naphthylmethyl group, a 2-naphthylmethyl group, 1-naphthylethyl group, and a 2-naphthylethyl group), and heterocyclic groups respectively represented by Formulae (r-hr-1) to (r-hr-6).

Examples of the alicyclic hydrocarbon group as the substituent for the condensed ring type group include: a group in which one hydrogen atom has been removed from monocycloalkanes such as cyclopentane and cyclohexane; a group in which one hydrogen atom has been removed from polycycloalkanes such as adamantan, norboman, isobornan, tricyclodecane, and tetracyclododecane; lactone-containing cyclic groups respectively represented by General Formulae (a2-r-1) to (a2-r-7); —SO₂— containing cyclic groups respectively represented by General Formulae (a5-r-1) to (a5-r-4); and heterocyclic groups respectively represented by Formulae (r-hr-7) to (r-hr-16).

Chain-Like Alkyl Group which May have Substituent:

The chain-like alkyl group as R¹⁰¹ may be linear or branched.

The linear alkyl group has preferably 1 to 20 carbon atoms, more preferably 1 to carbon atoms, and most preferably 1 to 10 carbon atoms.

The branched alkyl group has preferably 3 to 20 carbon atoms, more preferably 3 to 15, and most preferably 3 to 10. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-Like Alkenyl Group which May have Substituent:

A chain-like alkenyl group as R¹⁰¹ may be linear or branched, and the number of carbon atoms thereof is preferably 2 to 10, more preferably 2 to 5, still more preferably 2 to 4, and particularly preferably 3. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the above, the chain-like alkenyl group is preferably a linear alkenyl group, more preferably a vinyl group or a propenyl group, and particularly preferably a vinyl group.

Examples of the substituent for the chain-like alkyl group or alkenyl group as R¹⁰¹ include an alkoxy group, a halogen atom, a halogenated alkyl group, a hydroxy group, a carbonyl group, a nitro group, an amino group, and a cyclic group as R¹⁰¹.

Among the above, R¹⁰¹ is preferably a cyclic group which may have a substituent and more preferably a cyclic hydrocarbon group which may have a substituent. More specific examples of the cyclic hydrocarbon group include: groups in which one or more hydrogen atoms have been removed from a phenyl group, a naphthyl group, or a poly cycloalkane; lactone-containing cyclic groups respectively represented by General Formulae (a2-r-1) to (a2-r-7); and —SO₂-containing cyclic groups respectively represented by General Formulae (a5-r-1) to (a5-r-4).

In Formula (b-1), Y¹⁰¹ represents a single bond or a divalent linking group containing an oxygen atom.

In a case where Y¹⁰¹ represents a divalent linking group containing an oxygen atom, Y¹⁰¹ may contain an atom other than an oxygen atom. Examples of the atom other than an oxygen atom include a carbon atom, a hydrogen atom, a sulfur atom, and a nitrogen atom.

Examples of the divalent linking group containing an oxygen atom include: non-hydrocarbon-based oxygen atom-containing linking groups such as an oxygen atom (an ether bond; —O—), an ester bond (—C(═O)—O—), an oxycarbonyl group (—O—C(═O)—), an amide bond (—C(═O)—NH—), a carbonyl group (—C(═O)—), and a carbonate bond (—O—C(═O)—O—); and a combination of the non-hydrocarbon-based oxygen atom-containing linking groups and an alkylene group. A sulfonyl group (—SO₂—) may be further linked to this combination. Examples of the divalent linking group containing an oxygen atom include linking groups respectively represented by General Formulae (y-a1-1) to (y-a1-7).

[chemical structure]

[In the formulae, V′¹⁰¹ represents a single bond or an alkylene group having 1 to 5 carbon atoms, and V′¹⁰² represents a divalent saturated hydrocarbon group having 1 to 30 carbon atoms.]

The divalent saturated hydrocarbon group as V′¹⁰² is preferably an alkylene group having 1 to 30 carbon atoms, more preferably an alkylene group having 1 to 10 carbon atoms, and still more preferably an alkylene group having 1 to 5 carbon atoms.

The alkylene group as V′¹⁰¹ and V′¹⁰² may be a linear alkylene group or a branched alkylene group, and preferably a linear alkylene group.

Specific examples of the alkylene group as V′¹⁰¹ and V′¹⁰² include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂—, —CH₂CH(CH₃)CH₂CH₂—; and a pentamethylene group [—CH₂CH₂CH₂CH₂CH₂—].

Further, a part of methylene groups in the alkylene group as V′¹⁰¹ and V′¹⁰² may be substituted with a divalent aliphatic cyclic group having 5 to 10 carbon atoms. The aliphatic cyclic group is preferably a divalent group in which one hydrogen atom has been removed from the cyclic aliphatic hydrocarbon group (a monocyclic aliphatic hydrocarbon group or a polycyclic aliphatic hydrocarbon group) as Ra′³ in Formula (a1-r-1), and more preferably a cyclohexylene group, a 1,5-adamantylene group, or a 2,6-adamantylene group.

Y¹⁰¹ represents preferably a divalent linking group containing an ester bond or a divalent linking group containing an ether bond and more preferably linking groups respectively represented by Formulae (y-a1-1) to (y-a1-5).

In Formula (b-1), V¹⁰¹ represents a single bond, an alkylene group, or a fluorinated alkylene group. The alkylene group and the fluorinated alkylene group as V¹⁰¹ preferably have 1 to 4 carbon atoms. Examples of the fluorinated alkylene group as V¹⁰¹ include groups in which a part or all hydrogen atoms in the alkylene group as V¹⁰¹ have been substituted with fluorine atoms. Among them, V¹⁰¹ is preferably a single bond or a fluorinated alkylene group having 1 to 4 carbon atoms.

In Formula (b-1), R¹⁰² represents a fluorine atom or a fluorinated alkyl group having 1 to 5 carbon atoms. R¹⁰² represents preferably a fluorine atom or a perfluoroalkyl group having 1 to 5 carbon atoms and more preferably a fluorine atom.

Specific example of the anion moiety represented by Formula (b-1) include: in a case where Y¹⁰¹ represents a single bond, fluorinated alkylsulfonate anions such as a trifluoromethanesulfonate anion and a perfluorobutanesulfonate anion; and in a case where Y¹⁰¹ represents a divalent linking group containing an oxygen atom, anions represented by Formulae (an-1) to (an-3).

[chemical structure]

[In the formula, R″¹⁰¹ represents an aliphatic cyclic group which may have a substituent, monovalent heterocyclic groups respectively represented by Chemical Formulae (r-hr-1) to (r-hr-6), a condensed ring type group represented by Formula (r-br-1) or (r-br-2), and a chain-like alkyl group which may have a substituent. R″¹⁰² is an aliphatic cyclic group which may have a substituent, a condensed ring type group represented by Formula (r-br-1) or (r-br-2), lactone-containing cyclic groups respectively represented by General Formulae (a2-r-1), (a2-r-3) to (a2-r-7), -or SO₂-containing cyclic groups respectively represented by General Formulae (a5-r-1) to (a5-r-4). R″¹⁰³ represents an aromatic cyclic group which may have a substituent, an aliphatic cyclic group which may have a substituent, or a chain-like alkenyl group which may have a substituent. V″¹⁰¹ represents a single bond, an alkylene group having 1 to 4 carbon atoms, or a fluorinated alkylene group having 1 to 4 carbon atoms. R¹⁰² represents a fluorine atom or a fluorinated alkyl group having 1 to 5 carbon atoms, v″ each independently represents an integer of 0 to 3, q″ each independently represents an integer of 0 to 20, and n″ represents 0 or 1.]

The aliphatic cyclic group as R″¹⁰¹, R″¹⁰², and R″¹⁰³ which may have a substituent is preferably a group exemplified as the cyclic aliphatic hydrocarbon group as R¹⁰¹ in Formula (b-1). Examples of the substituent include the same groups as the substituent with which the cyclic aliphatic hydrocarbon group as R¹⁰¹ in Formula (b-1) may be substituted.

The aromatic cyclic group as R″¹⁰³, which may have a substituent, is preferably a group exemplified as the aromatic hydrocarbon group for the cyclic hydrocarbon group, as R¹⁰¹ in Formula (b-1). Examples of the substituent include the same group as the substituent with which the aromatic hydrocarbon group as R¹⁰¹ in Formula (b-1) may be substituted.

The chain-like alkyl group as R″¹⁰¹ which may have a substituent is preferably a group exemplified as the chain-like alkyl group as R¹⁰¹ in Formula (b-1).

The chain-like alkenyl group as R″¹⁰³ which may have a substituent is preferably a group exemplified as the chain-like alkenyl group as R¹⁰¹ in Formula (b-1).

Anion in Component (b-2)

In Formula (b-2), R¹⁰⁴ and R¹⁰⁵ each independently represent a cyclic group which may have a substituent, a chain-like alkyl group which may have a substituent, or a chain-like alkenyl group which may have a substituent, and R¹⁰⁴ and R¹⁰⁵ each have the same definition as that for R¹⁰¹ in Formula (b-1). R¹⁰⁴ and R¹⁰⁵ may be bonded to each other to form a ring.

As R¹⁰⁴ and R¹⁰⁵, a chain-like alkyl group which may have a substituent is preferable, and a linear or branched alkyl group or a linear or branched fluorinated alkyl group is more preferable.

The chain-like alkyl group has preferably 1 to 10 carbon atoms, more preferably 1 to 7 carbon atoms, and still more preferably 1 to 3 carbon atoms. It is preferable that the number of carbon atoms in the chain-like alkyl group as R¹⁰⁴ and R¹⁰⁵ is small because the solubility in a solvent for a resist is also excellent in the range of the number of carbon atoms. Further, in the chain-like alkyl group as R¹⁰⁴ and R¹⁰⁵, it is preferable that the number of hydrogen atoms substituted with fluorine atoms is large because the acid strength increases and the transparency to high energy radiation of 250 nm or less or electron beams is improved. The proportion of fluorine atoms in the chain-like alkyl group, that is, the fluorination ratio is preferably 70% to 100% and more preferably 90% to 100%, and it is most preferable that the chain-like alkyl group is a perfluoroalkyl group in which all hydrogen atoms are substituted with fluorine atoms.

In Formula (b-2), V¹⁰² and V¹⁰³ each independently represent a single bond, an alkylene group, or a fluorinated alkylene group, and V¹⁰² and V¹⁰³ each have the same definition as that for V¹⁰¹ in Formula (b-1).

In Formula (b-2), L¹⁰¹ and L¹⁰² each independently represent a single bond or an oxygen atom.

Anion in Component (b-3)

In Formula (b-3), R¹⁰⁶ to R¹⁰⁸ each independently represent a cyclic group which may have a substituent, a chain-like alkyl group which may have a substituent, or a chain-like alkenyl group which may have a substituent, and each example thereof is the same as R¹⁰¹ in Formula (b-1).

In Formula (b-3), L¹⁰³ to L¹⁰⁵ each independently represent a single bond, —CO—, or —SO₂—.

Among the above, the anion moiety of the component (B) is preferably an anion of the component (b-1). Among these, an anion represented by any one of General Formulae (an-1) to (an-3) is more preferable, an anion represented by any one of General Formula (an-1) or (an-2) is still more preferable, and an anion represented by General Formula (an-2) is particularly preferable.

[Cation Moiety]

In Formulae (b-1), (b-2), and (b-3), M′^{m+} represents an m-valent onium cation. Among these, a sulfonium cation and an iodonium cation are preferable, m represents an integer of 1 or more.

Examples of the preferred cation moiety ((M′^{m+})_{1/m}) include organic cations respectively represented by General Formulae (ca-1) to (ca-5).

[chemical structure]

[In the formula, R²⁰¹ to R²⁰⁷ and R²¹¹ to R²¹² each independently represent an aryl group, an alkyl group, or an alkenyl group, which may have a substituent. R²⁰¹ to R²⁰³, R²⁰⁶ to R²⁰⁷, and R²¹¹ to R²¹² may be bonded to each other to form a ring together with the sulfur atoms in the formulae. R²⁰⁸ and R²⁰⁹ each independently represent a hydrogen atom or an alkyl group having 1 to 5 carbon atoms. R²¹⁰ represents an aryl group which may have a substituent, an alkyl group which may have a substituent, an alkenyl group which may have a substituent, or a —SO₂-containing cyclic group which may have a substituent. L²⁰¹ represents —C(═O)— or —C(═O)—O—. Each Y²⁰¹ independently represent an arylene group, an alkylene group, or an alkenylene group, x represents 1 or 2. W²⁰¹ represents an (x+1)-valent linking group.]

In General Formulae (ca-1) to (ca-5), examples of the aryl group as R²⁰¹ to R²⁰⁷, R²¹¹, and R²¹² include an unsubstituted aryl group having 6 to 20 carbon atoms, and a phenyl group or a naphthyl group is preferable.

The alkyl group as R²⁰¹ to R²⁰⁷, R²¹¹, and R²¹² is a chain-like or cyclic alkyl group, and the number of carbon atoms thereof is preferably 1 to 30.

The alkenyl group as R²⁰¹ to R²⁰⁷, R²¹¹, and R²¹² preferably has 2 to 10 carbon atoms.

Examples of the substituent which may be included in R²⁰¹ to R²⁰⁷ and R²¹⁰ to R²¹² include an alkyl group, a halogen atom, a halogenated alkyl group, a carbonyl group, a cyano group, an amino group, an aryl group, and groups respectively represented by General Formulae (ca-r-1) to (ca-r-7).

[chemical structure]

[In the formulae, R′²⁰¹ s each independently represent a hydrogen atom, a cyclic group which may have a substituent, a chain-like alkyl group which may have a substituent, or a chain-like alkenyl group which may have a substituent.]

Cyclic Group which May have Substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. The aliphatic hydrocarbon group may be saturated or unsaturated. In general, the aliphatic hydrocarbon group is preferably saturated.

The aromatic hydrocarbon group as R′²⁰¹ is a hydrocarbon group having an aromatic ring. The aromatic hydrocarbon group has preferably 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. However, the number of carbon atoms in a substituent is not included in the number of carbon atoms.

Specific examples of the aromatic ring which the aromatic hydrocarbon group has as R′²⁰¹ include benzene, fluorene, naphthalene, anthracene, phenanthrene, biphenyl, and an aromatic hetero ring in which a part of carbon atoms constituting any of these aromatic rings have been substituted with hetero atoms. Examples of the hetero atom in the aromatic hetero rings include an oxygen atom, a sulfur atom, and a nitrogen atom.

Specific examples of the aromatic hydrocarbon group as R′²⁰¹ include a group in which one hydrogen atom has been removed from the above-described aromatic ring (an aryl group, for example, a phenyl group and a naphthyl group) and a group in which one hydrogen atom in the aromatic ring has been substituted with an alkylene group (for example, arylalkyl groups such as a benzyl group, a phenethyl group, a 1-naphthylmethyl group, a 2-naphthylmethyl group, 1-naphthylethyl group, and a 2-naphthylethyl group). The alkylene group (an alkyl chain in the arylalkyl group) has preferably 1 to 4 carbon atoms, more preferably 1 or 2 carbon atoms, and particularly preferably 1 carbon atom.

Examples of the cyclic aliphatic hydrocarbon group as R′²⁰¹ include an aliphatic hydrocarbon group containing a ring in the structure thereof.

Examples of the aliphatic hydrocarbon group containing a ring in the structure thereof include an alicyclic hydrocarbon group (a group in which one hydrogen atom has been removed from an aliphatic hydrocarbon ring), a group in which the alicyclic hydrocarbon group is bonded to the terminal of a linear or branched aliphatic hydrocarbon group, and a group in which the alicyclic hydrocarbon group is interposed in a linear or branched aliphatic hydrocarbon group.

The alicyclic hydrocarbon group has preferably 3 to 20 carbon atoms and more preferably 3 to 12 carbon atoms.

The alicyclic hydrocarbon group may be a polycyclic group or a monocyclic group. The monocyclic alicyclic hydrocarbon group is preferably a group in which one or more hydrogen atoms have been removed from a monocycloalkane. The monocycloalkane has preferably 3 to 6 carbon atoms, and specific examples thereof include cyclopentane and cyclohexane. The polycyclic alicyclic hydrocarbon group is preferably a group in which one or more hydrogen atoms have been removed from a polycycloalkane, and the number of carbon atoms of the polycycloalkane is preferably 7 to 30. Among them, the polycycloalkane is more preferably polycycloalkanes having a crosslinked ring-based polycyclic skeleton, such as adamantane, norbomane, isobornane, tricyclodecane, and tetracyclododecane, and polycycloalkanes having a condensed ring-based polycyclic skeleton, such as a cyclic group having a steroid skeleton.

Among them, the cyclic aliphatic hydrocarbon group as R′²⁰¹ is preferably a group in which one or more hydrogen atoms have been removed from a monocycloalkane or a polycycloalkane, more preferably a group in which one hydrogen atom has been removed from a polycycloalkane, particularly preferably an adamantyl group or a norbomyl group, and most preferably an adamantyl group.

The linear or branched aliphatic hydrocarbon group which may be bonded to the alicyclic hydrocarbon group has preferably 1 to 10 carbon atoms, more preferably 1 to 6 carbon atoms, still more preferably 1 to 4 carbon atoms, and particularly preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group is preferably a branched alkylene group, and specific examples thereof include alkylalkylene groups; for example, alkylmethylene groups such as —CH(CH₃)—, —CH(CH₂CH₃)—, —C(CH₃)₂—, —C(CH₃)(CH₂CH₃>, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. The alkyl group in the alkylalkylene group is preferably a linear alkyl group having 1 to 5 carbon atoms.

The cyclic hydrocarbon group as R′²⁰¹ may contain a hetero atom like a hetero ring or the like. Specific examples thereof include lactone-containing cyclic groups respectively represented by General Formulae (a2-r-1) to (a2-r-7), —SO₂-containing cyclic groups respectively represented by General Formulae (a5-r-1) to (a5-r-4), and other heterocyclic groups respectively represented by Chemical Formulae (r-hr-1) to (r-hr-16).

Examples of the substituent for the cyclic group as R′²⁰¹ include an alkyl group, an alkoxy group, a halogen atom, a halogenated alkyl group, a hydroxy group, a carbonyl group, and a nitro group.

The alkyl group as the substituent is preferably an alkyl group having 1 to 5 carbon atoms, and a methyl group, an ethyl group, a propyl group, an n-butyl group, or a tert-butyl group is most preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

The halogen atom as the substituent is preferably a fluorine atom.

Example of the above-described halogenated alkyl group as the substituent includes groups in which a part or all hydrogen atoms in alkyl groups having 1 to 5 carbon atoms such as a methyl group, an ethyl group, a propyl group, an n-butyl group, and a tert-butyl group have been substituted with the above-described halogen atoms.

The carbonyl group as the substituent is a group that is substituted for a methylene group (—CH₂—) constituting the cyclic hydrocarbon group.

Chain-Like Alkyl Group which May have Substituent:

The chain-like alkyl group as R′²⁰¹ may be linear or branched.

The linear alkyl group has preferably 1 to 20 carbon atoms, more preferably 1 to 15 carbon atoms, and most preferably 1 to 10 carbon atoms.

The branched alkyl group has preferably 3 to 20 carbon atoms, more preferably 3 to 15 carbon atoms, and most preferably 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-Like Alkenyl Group which May have Substituent:

The chain-like alkenyl group as R′²⁰¹ may be linear or branched, and has preferably 2 to 10 carbon atoms, more preferably 2 to 5 carbon atoms, still more preferably 2 to 4 carbon atoms, and particularly preferably 3 carbon atoms. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the above, the chain-like alkenyl group is preferably a linear alkenyl group, more preferably a vinyl group or a propenyl group, and particularly preferably a vinyl group.

Examples of the substituent for the chain-like alkyl group or alkenyl group as R′²⁰¹ include an alkoxy group, a halogen atom, a halogenated alkyl group, a hydroxy group, a carbonyl group, a nitro group, an amino group, and a cyclic group as R′²⁰¹.

Examples of the cyclic group which may have a substituent, the chain-like alkyl group which may have a substituent, or the chain-like alkenyl group which may have a substituent, as R′²⁰¹ include the same groups as the acid dissociable groups represented by Formula (a1-r-2), as the cyclic group which may have a substituent or the chain-like alkyl group which may have a substituent, in addition to the groups described above.

Among them, R′²⁰¹ is preferably a cyclic group which may have a substituent and more preferably a cyclic hydrocarbon group which may have a substituent. More specific examples of the cyclic hydrocarbon group include: groups in which one or more hydrogen atoms have been removed from a phenyl group, a naphthyl group, or a polycycloalkane; lactone-containing cyclic groups respectively represented by General Formulae (a2-r-1) to (a2-r-7); and —SO₂-containing cyclic groups respectively represented by General Formulae (a5-r-1) to (a5-r-4).

In General Formulae (ca-1) to (ca-5), in a case where R²⁰¹ to R²⁰³, R²⁰⁶ and R²⁰⁷, and R²¹¹ and R²¹² are bonded to each other to form a ring together with a sulfur atom in the formula, these groups may be bonded through a hetero atom such as a sulfur atom, an oxygen atom or a nitrogen atom, or a functional group such as a carbonyl group, —SO—, —SO₂—, —SO₃—, —COO—, —CONH— or —N(R_{N})— (here, R_{N} represents an alkyl group having 1 to 5 carbon atoms). As the ring to be formed, a ring containing the sulfur atom in the formula in the ring skeleton thereof is preferably a 3- to 10-membered ring and particularyl preferably a 5- to 7-membered ring, including the sulfur atom. Specific examples of the ring to be formed include a thiophene ring, a thiazole ring, a benzothiophene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

R²⁰⁸ and R²⁰⁹ each independently represent a hydrogen atom or an alkyl group having 1 to 5 carbon atoms and are preferably a hydrogen atom or an alkyl group having 1 to 3 carbon atoms. In a case where R²⁰⁸ and R²⁰⁹ each independently represent an alkyl group, R²⁰⁸ and R²⁰⁹ may be bonded to each other to form a ring.

R²¹⁰ represents an aryl group which may have a substituent, an alkyl group which may have a substituent, an alkenyl group which may have a substituent, or a —SO₂— containing cyclic group which may have a substituent.

Examples of the aryl group as R²¹⁰ include an unsubstituted aryl group having 6 to 20 carbon atoms, and a phenyl group or a naphthyl group is preferable.

The alkyl group as R²¹⁰ is preferably a chain-like or cyclic alkyl group having 1 to 30 carbon atoms.

The alkenyl group as R²¹⁰ preferably has 2 to 10 carbon atoms. The —SO₂-containing cyclic group which may have a substituent, as R²¹⁰, is preferably a “—SO₂-containing polycyclic group” and more preferably a group represented by General Formula (a5-r-1).

Each Y²⁰¹ independently represent an arylene group, an alkylene group, or an alkenylene group.

Examples of the arylene group as Y²⁰¹ include groups in which one hydrogen atom has been removed from an aryl group mentioned as the aromatic hydrocarbon group represented by R¹⁰¹ in Formula (b-1) described above.

Examples of the alkylene group and the alkenylene group, as Y²⁰¹, include groups in which one hydrogen atom has been removed from the chain-like alkyl group or the chain-like alkenyl group as R¹⁰¹ in Formula (b-1) described above.

In Formula (ca-4), x represents 1 or 2.

W²⁰¹ represents an (x+1)-valent linking group, that is, a divalent or trivalent linking group.

The divalent linking group as W²⁰¹ is preferably a divalent hydrocarbon group which may have a substituent, and an example thereof include the same divalent hydrocarbon group (which may have a substituent) as Ya²¹ in General Formula (a2-1)) described above. The divalent linking group as W²⁰¹ may be linear, branched, or cyclic, and preferably cyclic. Among them, a group in which two carbonyl groups are combined at both terminals of an arylene group is preferable. Examples of the arylene group include a phenylene group and a naphthylene group, and a phenylene group is particularly preferable.

Examples of the trivalent linking group as W²⁰¹ include a group in which one hydrogen atom has been removed from the above-described divalent linking group as W²⁰¹ and a group in which the divalent linking group has been bonded to another divalent linking group. The trivalent linking group as W²⁰¹ is preferably a group in which two carbonyl groups are bonded to an arylene group.

Specific examples of the suitable cation represented by Formula (ca-1) include cations respectively represented by Chemical Formulae (ca-1-1) to (ca-1-70).

[chemical structure]

[chemical structure]

[chemical structure]

[chemical structure]

[chemical structure]

[chemical structure]

[chemical structure]

[chemical structure]

[chemical structure]

[chemical structure]

[chemical structure]

[In the formula, g1, g2, and g3 represent the numbers of repetitions, g1 represents an integer of 1 to 5, g2 represents an integer of 0 to 20, and g3 represents an integer of 0 to 20.]

[chemical structure]

[chemical structure]

[chemical structure]

[chemical structure]

[chemical structure]

[In the formula, R″²⁰¹ represents a hydrogen atom or a substituent, and the substituent is the same as that mentioned as the substituent that R²⁰¹ to R²⁰⁷ and R²¹⁰ to R²¹² may have.]

Specific examples of the suitable cation represented by Formula (ca-2) include a diphenyliodonium cation and a bis(4-tert-butylphenyl)iodonium cation.

Specific examples of the suitable cation represented by Formula (ca-3) include cations respectively represented by Formulae (ca-3-1) and (ca-3-6).

[chemical structure]

Specific examples of the suitable cation represented by Formula (ca-4) include cations respectively represented by Formulae (ca-4-1) and (ca-4-2).

[chemical structure]

Specific examples of the suitable cation represented by Formula (ca-5) include cations respectively represented by General Formulae (ca-5-1) to (ca-5-3).

[chemical structure]

Among the above, the cation moiety ((M′^{m+})_{1/m}) is preferably a cation represented by General Formula (ca-1).

In the resist composition of the present embodiment, the component (B) may be used alone or in a combination of two or more kinds thereof.

In a case where the resist composition contains the component (B), the content of the component (B) in the resist composition is preferably less than 50 parts by mass, more preferably 1 to 40 parts by mass, and still more preferably 3 to 25 parts by mass with respect to 100 parts by mass of the component (A).

In a case where the content of the component (B) is set to be in the preferred range described above, pattern formation can be satisfactorily performed. Further, in a case where each component of the resist composition is dissolved in an organic solvent, the above range is preferable since a uniform solution is easily obtained and the storage stability of the resist composition is improved.

«Base Component (D)»

The resist composition of the present embodiment may further contain, in addition to the components (A), a base component (component (D)) that traps an acid (that is, controls the diffusion of an acid) generated by exposure. The component (D) acts as a quencher (an acid diffusion controlling agent) which traps the acid generated in the resist composition upon exposure.

Examples of the component (D) include a photodegradable base (D1) (hereinafter, referred to as the “component (D1)”) that is decomposed upon exposure and loses the acid diffusion controllability and a nitrogen-containing organic compound (D2) (hereinafter, referred to as the “component (D2)”) which does not correspond to the component (D1). Among these, a photodegradable base (component (D1)) is preferable since it is easy to enhance all of the characteristics of the high sensitivity, the reduction of roughness, and the suppression of the occurrence of coating defects.

In Regard to Component (D1)

In a case where a resist composition containing the component (D1) is obtained, the contrast between the exposed portion and the unexposed portion of the resist film can be further improved at the time of the formation of a resist pattern. The component (D1) is not particularly limited as long as the component is decomposed upon exposure and loses the acid diffusion controllability, and one or more compounds selected from the group consisting of a compound represented by General Formula (d1-1) (hereinafter, referred to as the “component (d1-1)”), a compound represented by General Formula (d1-2) (hereinafter, referred to as the “component (d1-2)”), and a compound represented by General Formula (d1-3) (hereinafter, referred to as the “component (d1-3)”) are preferable.

At the exposed portion of the resist film, the components (d1-1) to (d1-3) are decomposed and then lose the acid diffusion controllability (basicity), and thus the components (d1-1) to (d1-3) cannot act as a quencher, whereas the components (d1-1) to (d1-3) act as a quencher at the unexposed portion of the resist film.

[chemical structure]

[In the formulae, Rd¹ to Rd⁴ represent a cyclic group which may have a substituent, a chain-like alkyl group which may have a substituent, or a chain-like alkenyl group which may have a substituent. However, a fluorine atom is not bonded to the carbon atom adjacent to the S atom in Rd² in Formula (d1-2). Yd¹ represents a single bond or a divalent linking group, m represents an integer of 1 or more, and each M^{m+} independently represents an m-valent organic cation.]

{Component (d1-1)}

Anion Moiety

In Formula (d1-1), Rd¹ represents a cyclic group which may have a substituent, a chain-like alkyl group which may have a substituent, or a chain-like alkenyl group which may have a substituent, and each example thereof is the same as R′²⁰¹ described above.

Among these, Rd¹ is preferably an aromatic hydrocarbon group which may have a substituent, an aliphatic cyclic group which may have a substituent, or a chain-like alkyl group which may have a substituent. Examples of the substituent which these groups may have include a hydroxy group, an oxo group, an alkyl group, an aryl group, a fluorine atom, a fluorinated alkyl group, lactone-containing cyclic groups respectively represented by General Formulae (a2-r-1) to (a2-r-7), an ether bond, an ester bond, and a combination thereof. In a case where an ether bond or an ester bond is included as the substituent, the substituent may be bonded through an alkylene group, and the substituent in this case is preferably linking groups respectively represented by Formulae (y-a1-1) to (y-a1-5).

Examples of the aromatic hydrocarbon group preferably include a phenyl group, a naphthyl group, and a polycyclic structure (a polycyclic structure including a bicyclooctane skeleton and a ring structure other than the bicyclooctane skeleton) including a bicyclooctane skeleton.

The aliphatic cyclic group is preferably a group in which one or more hydrogen atoms have been removed from polycycloalkanes such as adamantane, norbomane, isobornane, tricyclodecane, and tetracyclododecane.

The chain-like alkyl group preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl group, or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, or a 4-methylpentyl group.

In a case where the chain-like alkyl group is a fluorinated alkyl group having a fluorine atom or a fluorinated alkyl group as a substituent, the fluorinated alkyl group has preferably 1 to 11 carbon atoms, more preferably 1 to 8 carbon atoms, and still more preferably 1 to 4 carbon atoms. The fluorinated alkyl group may contain an atom other than a fluorine atom. Examples of the atom other than a fluorine atom include an oxygen atom, a sulfur atom, and a nitrogen atom.

Rd¹ is preferably a fluorinated alkyl group in which a part or all of the hydrogen atoms constituting a linear alkyl group have been substituted with fluorine atoms and particularly preferably a fluorinated alkyl group in which all of the hydrogen atoms constituting a linear alkyl group have been substituted with fluorine atoms (a linear perfluoroalkyl group).

Specific examples of the preferred anion moiety for the component (d1-1) are as follows.

[chemical structure]

[chemical structure]

Cation Moiety

In Formula (d1-1), M^{m+} represents an m-valent organic cation.

Suitable examples of the organic cation of M^{m+} include the same cations as those respectively represented by General Formulae (ca-1) to (ca-5) and is more preferably a cation represented by General Formula (ca-1) and still more preferably cations respectively represented by Formulae (ca-1-1) to (ca-1-70).

The component (d1-1) may be used alone or in a combination of two or more kinds thereof.

{Component (d1-2)}

Anion Moiety

In Formula (d1-2), Rd² represents a cyclic group which may have a substituent, a chain-like alkyl group which may have a substituent, or a chain-like alkenyl group which may have a substituent, and an example thereof is the same as R′²⁰¹ described above.

However, a fluorine atom is not bonded to the carbon atom adjacent to the S atom in Rd² (the carbon atom adjacent to the S atom in Rd² is not substituted with a fluorine atom). As a result, the anion of the component (d1-2) becomes an appropriately weak acid anion, thereby improving the quenching ability of the component (D).

Rd² is preferably a chain-like alkyl group which may have a substituent or an aliphatic cyclic group which may have a substituent. The chain-like alkyl group has preferably 1 to 10 carbon atoms and more preferably 3 to 10 carbon atoms. The aliphatic cyclic group is preferably a group in which one or more hydrogen atoms have been removed from adamantane, norbornane, isobornane, tricyclodecane, or tetracyclododecane (which may have a substituent) and a group in which one or more hydrogen atoms have been removed from camphor.

The hydrocarbon group as Rd² may have a substituent. Examples of the substituent include the same group as the substituent which may be included in the hydrocarbon group (such as an aromatic hydrocarbon group, an aliphatic cyclic group, or a chain-like alkyl group) as Rd¹ in Formula (d1-1).

Specific examples of the preferred anion moiety for the component (d1-2) are as follows.

[chemical structure]

Cation Moiety

In Formula (d1-2), M^{m+} represents an m-valent organic cation and is the same as M^{m+} in Formula (d1-1).

The component (d1-2) may be used alone or in a combination of two or more kinds thereof.

{Component (d1-3)}

Anion Moiety

In Formula (d1-3), Rd³ represents a cyclic group which may have a substituent, a chain-like alkyl group which may have a substituent, or a chain-like alkenyl group which may have a substituent. An example of Rd³ includes the same group as R′²⁰¹, and a cyclic group containing a fluorine atom, a chain-like alkyl group, or a chain-like alkenyl group is preferable. Among them, a fluorinated alkyl group is preferable, and the same fluorinated alkyl group as that of Rd¹ is more preferable.

In Formula (d1-3), Rd⁴ represents a cyclic group which may have a substituent, a chain-like alkyl group which may have a substituent, or a chain-like alkenyl group which may have a substituent, and examples thereof are the same as R′²⁰¹ described above.

Among them, an alkyl group which may have a substituent, an alkoxy group which may have a substituent, an alkenyl group which may have a substituent, or a cyclic group which may have a substituent is preferable.

The alkyl group as Rd⁴ is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. A part of hydrogen atoms in the alkyl group as Rd⁴ may be substituted with a hydroxy group, a cyano group, or the like.

The alkoxy group as Rd⁴ is preferably an alkoxy group having 1 to 5 carbon atoms, and specific examples of the alkoxy group having 1 to 5 carbon atoms include a methoxy group, an ethoxy group, an n-propoxy group, an iso-propoxy group, an n-butoxy group, and a tert-butoxy group. Among them, a methoxy group and an ethoxy group are preferable.

Examples of the alkenyl group as Rd⁴ include the same group as the alkenyl groups as R′²⁰¹, and a vinyl group, a propenyl group (an allyl group), a 1-methylpropenyl group, and a 2-methylpropenyl group are preferable. These groups may further have an alkyl group having 1 to 5 carbon atoms or a halogenated alkyl group having 1 to 5 carbon atoms, as a substituent.

Examples of the cyclic group as Rd⁴ include the same groups as the cyclic groups as R′²⁰¹ and alicyclic groups in which one or more hydrogen atoms have been removed from cycloalkanes such as cyclopentane, cyclohexane, adamantane, norbornane, isobornane, tricyclodecane, and tetracyclododecane, or aromatic groups such as a phenyl group and a naphthyl group are preferable. In a case where Rd⁴ represents an alicyclic group, the resist composition can be satisfactorily dissolved in an organic solvent, thereby improving the lithography characteristics. In a case where Rd⁴ is an aromatic group, the resist composition is excellent in light absorption efficiency and thus has good sensitivity and lithography characteristics in the lithography using EUV or the like as a light source for exposure.

In Formula (d1-3), Yd¹ represents a single bond or a divalent linking group.

The divalent linking group as Yd¹ is not particularly limited, and examples thereof include a divalent hydrocarbon group (an aliphatic hydrocarbon group or an aromatic hydrocarbon group) which may have a substituent and a divalent linking group containing a hetero atom. As these divalent linking groups, the same groups as those described above as the divalent hydrocarbon group which may have a substituent and the divalent linking group containing a hetero atom described above as the divalent linking group as Ya²¹ in Formula (a2-1) can be respectively mentioned.

Yd¹ is preferably a carbonyl group, an ester bond, an amide bond, an alkylene group, or a combination of thereof. The alkylene group is more preferably a linear or branched alkylene group and still more preferably a methylene group or an ethylene group.

Specific examples of the preferred anion moiety for the component (d1-3) are as follows.

[chemical structure]

[chemical structure]

[chemical structure]

Cation Moiety

In Formula (d1-3), M^{m+} represents an m-valent organic cation and is the same as M^{m+} in Formula (d1-1).

The component (d1-3) may be used alone or in a combination of two or more kinds thereof.

As the component (D1), any one of the above-described components (d1-1) to (d1-3) may be used alone, or a combination of two or more kinds thereof may be used.

In a case where the resist composition contains the component (D1), the content of the component (D1) in the resist composition is preferably 0.5 to 20 parts by mass and more preferably 1 to 15 parts by mass, with respect to 100 parts by mass of the component (A).

In a case where the content of the component (D1) is equal to or greater than the preferred lower limit, excellent lithography characteristics and an excellent resist pattern shape are easily obtained. On the other hand, in a case where the content of the component (D1) is equal to or lower than the upper limit, the sensitivity can be maintained satisfactorily and the throughput is also excellent.

Method of Producing Component (D1):

The method of producing the components (d1-1) and (d1-2) are not particularly limited, and the components (d1-1) and (d1-2) can be produced by a conventionally known method.

Further, the method of producing the component (d1-3) is not particularly limited, and the component (d1-3) can be produced in the same manner as disclosed in United States Patent Application, Publication No. 2012-0149916.

in Regard to Component (D2)

The component (D) may contain a nitrogen-containing organic compound component (hereinafter, referred to as the “component (D2)”) which does not correspond to the above-mentioned component (D1).

The component (D2) is not particularly limited as long as it acts as an acid diffusion controlling agent and does not correspond to the component (D1), and any conventionally known compound may be used. Among them, an aliphatic amine is preferable, and among the aliphatic amines, a secondary aliphatic amine or a tertiary aliphatic amine is more preferable.

The aliphatic amine is an amine having one or more aliphatic groups, and the aliphatic groups preferably have 1 to 12 carbon atoms.

Examples of the aliphatic amines include an amine in which at least one hydrogen atom of ammonia (NH₃) has been substituted with an alkyl group or hydroxyalkyl group having 12 or fewer carbon atoms (an alkylamine or an alkylalcoholamine) and a cyclic amine.

Specific examples of the alkylamine and the alkylalcoholamine include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkylalcoholamines such as diethanolamine, triethanolamine, diisopropanolamine, triisopropanolamine, di-n-octanolamine, and tri-n-octanolamine. Among these, a trialkylamine having 5 to 10 carbon atoms is still more preferable, and tri-n-pentylamine or tri-n-octylamine is particularly preferable.

Examples of the cyclic amine include heterocyclic compounds containing a nitrogen atom as a hetero atom. The heterocyclic compound may be a monocyclic compound (aliphatic monocyclic amine) or a polycyclic compound (aliphatic polycyclic amine).

Specific examples of the aliphatic monocyclic amine include piperidine and piperazine. The aliphatic polycyclic amine preferably has 6 to 10 carbon atoms, and specific examples thereof include 1, 5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris {2-(2-methoxyethoxy)ethyl}amine, tris {2-(2-methoxyethoxymethoxy)ethyl}amine, tris{2-(1-methoxyethoxy)ethyl}amine, tris{2-(l-ethoxyethoxy)ethyl}amine, tris{2-(1-ethoxypropoxy)ethyl}amine, tris [2-{2-(2-hydroxyethoxy)ethoxy}ethyl]amine, and triethanolamine triacetate, and triethanolamine triacetate is preferable.

In addition, as the component (D2), an aromatic amine may be used.

Examples of the aromatic amine include 4-dimethylaminopyridine, pyrrole, indole, pyrazole, imidazole, or a derivative thereof, tribenzylamine, 2,6-diisppropylaniline, and N-tert-butoxycarbonylpyrrolidine.

The component (D2) may be used alone or in a combination of two or more kinds thereof. In a case where the resist composition contains the component (D2), the content of the component (D2) in the resist composition is typically used in a range of 0.01 to 5 parts by mass with respect to 100 parts by mass of the component (A). By setting the content within the above range, the resist pattern shape, the post-exposure temporal stability, and the like are improved.

“At Least One Compound (E) Selected from the Group Consisting of Organic Carboxylic Acid, Phosphorus Oxo Acid, and Derivatives Thereof”

For the purpose of preventing any deterioration in sensitivity and improving the resist pattern shape and post-exposure temporal stability, the resist composition of the present embodiment may contain, as an optional component, at least one compound (E) (hereinafter referred to as the component (E)) selected from the group consisting of an organic carboxylic acid, and a phosphorus oxo acid and a derivative thereof.

Suitable examples of the organic carboxylic acid include acetic acid, malonic acid, citric acid, malic acid, succinic acid, benzoic acid, and salicylic acid.

Examples of the phosphorus oxo acid include phosphoric acid, phosphonic acid, and phosphinic acid. Among these, phosphonic acid is particularly preferable. Examples of the phosphorus oxo acid derivative include esters in which a hydrogen atom in the above-described oxo acids is substituted with a hydrocarbon group. Examples of the hydrocarbon group include an alkyl group having 1 to 5 carbon atoms and an aryl group having 6 to 15 carbon atoms.

Examples of the phosphoric acid derivative include phosphoric acid esters such as di-n-butyl phosphate and diphenyl phosphate.

Examples of the phosphonic acid derivative include phosphonic acid esters such as dimethyl phosphonate, di-n-butyl phosphonate, phenylphosphonic acid, diphenyl phosphonate, and dibenzyl phosphonate.

Examples of the phosphinic acid derivative include a phosphinic acid ester and phenylphosphinic acid.

In the resist composition of the present embodiment, the component (E) may be used alone or in a combination of two or more kinds thereof.

In a case where the resist composition contains the component (E), the content of the component (E) is typically used in a range of 0.01 to 5 parts by mass with respect to 100 parts by mass of the component (A).

“Fluorine Additive Component (F)”

The resist composition of the present embodiment may further contain a fluorine additive component (hereinafter, referred to as the “component (F)”) in order to impart water repellency to the resist film or to improve lithography characteristics.

As the component (F), a fluorine-containing polymer compound described in Japanese Unexamined Patent Application, First Publication No. 2010-002870, Japanese Unexamined Patent Application, First Publication No. 2010-032994, Japanese Unexamined Patent Application, First Publication No. 2010-277043, Japanese Unexamined Patent Application, First Publication No. 2011-13569, or Japanese Unexamined Patent Application, First Publication No. 2011-128226 can be used.

Specific examples of the component (F) include polymers having a constitutional unit (f1) represented by General Formula (f1-1). The polymer is preferably a copolymer of the constitutional unit (f1) represented by Formula (f1-1) and the constitutional unit (a4) described above.

[chemical structure]

[In the formula, R is the same as that described above. Rf¹⁰² and Rf¹⁰³ each independently represent a hydrogen atom, a halogen atom, an alkyl group having 1 to 5 carbon atoms, or a halogenated alkyl group having 1 to 5 carbon atoms, and Rf¹⁰² and Rf¹⁰³ may be the same or different from each other, nf¹ represents an integer of 0 to 5. Rf¹⁰¹ represents an organic group containing a fluorine atom.]

In Formula (f1-1), R bonded to the carbon atom at the α-position is the same as that described above. R is preferably a hydrogen atom or a methyl group.

In Formula (f1-1), the halogen atom of Rf¹⁰² and Rf¹⁰³ is preferably a fluorine atom. Examples of the alkyl group having 1 to 5 carbon atoms as Rf¹⁰² and Rf¹⁰³ include the same groups as the alkyl groups having 1 to 5 carbon atoms as R, and a methyl group or an ethyl group is preferable. Specific examples of the halogenated alkyl group having 1 to 5 carbon atoms as Rf¹⁰² and Rf¹⁰³ include groups in which a part or all hydrogen atoms of the above-described alkyl groups of 1 to 5 carbon atoms have been substituted with halogen atoms. The halogen atom is preferably a fluorine atom. Among them, Rf¹⁰² and Rf¹⁰³ are preferably a hydrogen atom, a fluorine atom, or an alkyl group having 1 to 5 carbon atoms and ore preferably a hydrogen atom, a fluorine atom, a methyl group, or an ethyl group.

In Formula (f1-1), nf¹ represents an integer of 0 to 5, preferably an integer of 0 to 3, and more preferably an integer of 0.

In Formula (f1-1), Rf¹⁰¹ represents an organic group containing a fluorine atom and is preferably a hydrocarbon group containing a fluorine atom.

The hydrocarbon group containing a fluorine atom may be linear, branched, or cyclic, and has preferably 1 to 20 carbon atoms, more preferably 1 to 15 carbon atoms, and particularly preferably 1 to 10 carbon atoms.

In addition, in the hydrocarbon group containing a fluorine atom, preferably 25% or more of the hydrogen atoms in the hydrocarbon group are fluorinated, more preferably 50% or more are fluorinated, and particularly preferably 60% or more are fluorinated, since the hydrophobicity of the resist film at the time of dipping exposure increases.

Among them, Rf¹⁰¹ is preferably a fluorinated hydrocarbon group having 1 to 6 carbon atoms and more preferably a trifluoromethyl group, —CH₂—CF₃, —CH₂—CF₂—CF₃, —CH(CF₃)₂, —CH₂—CH₂—CF₃, and —CH₂—CH₂—CF₂—CF₂—CF₂—CF₃.

The weight-average molecular weight (Mw) (based on the polystyrene-equivalent value determined by gel permeation chromatography) of the component (F) is preferably 1,000 to 50,000, more preferably 5,000 to 40,000, and most preferably 10,000 to 30,000. In a case where the weight-average molecular weight is equal to or lower than the upper limit of the above-described range, the resist composition exhibits a solubility in a solvent for a resist, which is enough for using the resist composition as a resist composition. On the other hand, in a case where the weight-average molecular weight is equal to or greater than the lower limit of the above-described range, water repellency of the resist film is excellent.

Further, the polydispersity (Mw/Mn) of the component (F) is preferably 1.0 to 5.0, more preferably 1.0 to 3.0, and most preferably 1.0 to 2.5.

In the resist composition of the present embodiment, the component (F) may be used alone or in a combination of two or more kinds thereof.

In a case where the resist composition contains the component (F), the content of the component (F) is typically used in a proportion of 0.5 to 10 parts by mass, with respect to 100 parts by mass of the component (A).

“Organic Solvent Component (S)”

The resist composition of the present embodiment may be produced by dissolving the resist materials in an organic solvent component (hereinafter, referred to as the “component (S)”).

The component (S) may be any organic solvent which can dissolve each of the components to be used to obtain a uniform solution, and any organic solvent can be properly selected and used from those which have been conventionally known as solvents for a chemical amplification type resist composition. The components (S) preferably contains a carbonate-based organic solvent (S1) (hereinafter, also referred to as “component (S1)”).

Carbonate-Based Organic Solvent (S1)

In a case where the resist composition of the present embodiment contains the component (S1), the generation of residues can be suppressed in the resist pattern formation since the solubility of the component (A1) described above can be improved.

Suitable examples of the carbonate-based organic solvent (S1) include the following compounds, and among them, propylene carbonate is more preferable.

[chemical structure]

In the resist composition of the present embodiment, the component (S1) may be used singly or as a mixed solvent of two or more solvents.

In a case where the resist composition contains the component (S1), the content of the component (S1) is preferably 0.5 to 100 parts by mass and more preferably 10 to 80 parts by mass, with respect to 100 parts by mass of the component (A).

In the component (S) of the resist composition of the present embodiment, the component (S1) is preferably used in combination with an organic solvent (S2) (hereinafter, also referred to as “component (S2)”) that does not correspond to the component (S1).

Organic Solvent (S2)

Examples of the component (S2) include lactones such as γ-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkyl ether (such as monomethyl ether, monoethyl ether, monopropyl ether or monobutyl ether) or monophenyl ether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzyl ether, cresylmethyl ether, diphenyl ether, dibenzyl ether, phenetole, butylphenyl ether, ethylbenzene, diethylbenzene, pentylbenzene, isopropylbenzene, toluene, xylene, cymene and mesitylene; and dimethylsulfoxide (DMSO).

Among the above, the component (S2) is preferably PGMEA, PGME, γ-butyrolactone, EL, or cyclohexanone.

In the resist composition of the present embodiment, the component (S2) may be used singly or as a mixed solvent of two or more solvents.

In the resist composition of the present embodiment, the component (S) preferably contains a carbonate-based organic solvent (S1) and is preferably a mixed solvent of the carbonate-based organic solvent (S1) and one or more organic solvent selected from the group consisting of PGMEA, PGME, γ-butyrolactone, EL, and cyclohexanone.

The content of the component (S) is not particularly limited and is properly set, depending on the thickness of a film to be coated, to a concentration at which the component (S) can be applied onto a substrate or the like. Generally, the component (S) is used such that the concentration of solid contents of the resist composition is in the range of 0.1% to 20% by mass and preferably 0.2% to 15% by mass.

Further, as desired, other miscible additives can be properly added to the resist composition of the present embodiment. Examples of the miscible additives include an additive resin, a dissolution inhibitor, a plasticizer, a stabilizer, a colorant, a halation prevention agent, and a dye for improving the performance of a resist film.

After dissolving the resist material in the component (S), the resist composition of the present embodiment may be subjected to removing impurities and the like by using a porous polyimide film, a porous polyamideimide film, or the like. For example, the resist composition may be filtered using a filter made of a porous polyimide film, a filter made of a porous polyamideimide film, or a filter made of a porous polyimide film and a porous polyamideimide film. An example of the porous polyimide film and the porous polyamideimide film include the film disclosed in Japanese Unexamined Patent Application, First Publication No. 2016-155121.

The above-described resist composition of the present embodiment contains a polymer compound having the constitutional unit (a01) and the constitutional unit (a02), which are described above, and a proportion of the constitutional unit (a01) is more than 50% by mole and 70% by mole or less with respect to a total amount (100% by mole) of all constitutional units constituting the polymer compound.

Since the resist composition of the present embodiment contains a polymer compound that contains a large number of the constitutional units (a01), the reactivity to deprotection reaction is high. Further, since the polymer compound has the constitutional unit (a02), having the effects obtained by appropriately adjusting the acid diffusion length, increasing the adhesiveness of the resist film to the substrate, appropriately adjusting the solubility during development, and the like, the deterioration of CDU due to the improvement of reactivity can be suppressed. In addition, since the polymer compound has a highly rigid constitutional unit (a02), etching resistance can also be improved. Due to these synergistic effects, the resist composition of the present embodiment is excellent in both CDU and etching resistance.

Further, in the resist composition of the present embodiment, the solubility of the polymer compound is improved since the above-described component (S1) is contained in addition to the above-described polymer compound having the constitutional unit (a01) and the constitutional unit (a02), whereby the generation of residues can be suppressed in the formation of the resist pattern.

(Method of Forming Resist Pattern)

The method of forming a resist pattern according to the second aspect of the present invention is a method including a step of forming a resist film on a support using the resist composition according to the first aspect of the present invention described above, a step of exposing the resist film, and a step of developing the exposed resist film to form a resist pattern.

An example of one embodiment of such a method of forming a resist pattern include a method of forming a resist pattern performed as described below.

First, the above-described resist composition of the embodiment is applied onto a support with a spinner or the like, and a baking (post-apply baking (PAB)) treatment is performed, for example, at the temperature condition of 80° C. to 150° C. for 40 to 120 seconds, preferably for 60 to 90 seconds, to form a resist film.

Following the selective exposure performed on the resist film by, for example, the light exposure through a mask (mask pattern) having a predetermined pattern formed on the mask by using a lithography apparatus, for example, an electron beam lithography apparatus and an EUV exposure apparatus, or by the direct irradiation of the resit film for drawing with electron beam without using a mask pattern, baking treatment (post-exposure baking (PEB)) is performed, for example, under the temperature condition of 80° C. to 150° C. for 40 to 120 seconds and preferably 60 to 90 seconds.

Next, the resist film is subjected to a developing treatment. The developing treatment is performed using an alkali developing solution in a case of an alkali developing process, and a developing solution containing an organic solvent (organic developing solution) in a case of a solvent developing process.

The method of forming a resist pattern of the present embodiment is particularly useful in a case where the developing treatment is carried out by a solvent developing process using a developing solution containing an organic solvent, from the viewpoint of further improving the effects of the present invention.

After the developing treatment, it is preferable to perform rinsing treatment. In a case of an alkali developing process, the rinsing treatment is preferably water rinsing using pure water, and in a case of a solvent developing process, a rinse liquid containing an organic solvent is preferably used.

In a case of a solvent developing process, after the developing treatment or the rinsing treatment, the developing solution or the rinse liquid remaining on the pattern can be removed by a treatment using a supercritical fluid.

After the developing treatment or the rinsing treatment, drying is performed. As desired, baking treatment (post-baking) can be performed following the developing treatment.

In this manner, a resist pattern can be formed.

The support is not particularly limited and a conventionally known support can be used. Examples thereof include a substrate for electronic components, and a substrate for electronic components, having a wiring pattern formed on the substrate. More specific examples of the substrate include silicon wafer, substrates made of metals such as copper, chromium, iron, and aluminum, and a glass substrate. As the material for a wiring pattern, copper, aluminum, nickel, or gold can be used.

Further, as the support, any support having the above-described substrate on which an inorganic and/or an organic film is provided may be used. An example of the inorganic film includes an inorganic antireflection film (inorganic BARC). Examples of the organic film include an organic antireflection film (organic BARC) and an organic film such as a lower-layer organic film used in a multilayer resist method.

Here, the multilayer resist method is a method in which at least one layer of an organic film (lower-layer organic film) and at least one layer of a resist film (upper-layer resist film) are provided on a substrate, and a resist pattern formed on the upper-layer resist film is used as a mask to perform patterning of the lower-layer organic film. This method is considered as a method capable of forming a pattern having a high aspect ratio. That is, according to the multilayer resist method, a desired thickness can be ensured by the lower-layer organic film, and as a result, the thickness of the resist film can be reduced, and thus a fine pattern with a high aspect ratio can be formed.

The multilayer resist method is classified into a method (double-layer resist method) in which a double-layer structure consisting of an upper-layer resist film and a lower-layer organic film is formed, and a method (triple-layer resist method) in which a multilayer structure having three or more layers that include one or more intermediate layers (thin metal films or the like) provided between the upper-layer resist film and the lower-layer organic film is formed.

The wavelength to be used for exposure is not particularly limited and the exposure can be performed using radiation such as an ArF excimer laser, a KrF excimer laser, an F₂ excimer laser, extreme ultraviolet (EUV) rays, vacuum ultraviolet (VUV) rays, electron beams (EB), X-rays, and soft X-rays. The resist composition is highly useful for a KrF excimer laser, an ArF excimer laser, EB, or EUV, more useful for an ArF excimer laser, EB or EUV, and particularly useful for EB or EUV. That is, the method of forming a resist pattern of the present embodiment is a particularly useful method in a case where the step of exposing the resist film includes an operation of exposing the resist film to extreme ultraviolet (EUV) rays or electron beams (EB).

In the method of exposing the resist film, a general light exposure (dry light exposure) performed in air or an inert gas such as nitrogen may be used, or liquid immersion lithography may be used.

In liquid immersion lithography, the region between the resist film and the lens at the lowermost point of the lithography apparatus is pre-filled with a solvent (liquid immersion medium) that has a refractive index higher than the refractive index of air, and light exposure (dipping exposure) is performed in this state.

The liquid immersion medium is preferably a solvent that has a refractive index higher than the refractive index of air but lower than the refractive index of the resist film to be exposed. The refractive index of the solvent is not particularly limited as long as it satisfies the above-described requirements.

Examples of the solvent which exhibits a refractive index that is higher than the refractive index of air but lower than the refractive index of the resist film include water, a fluorine-based inert liquid, a silicone-based solvent, and a hydrocarbon-based solvent.

Specific examples of the fluorine-based inert liquid include liquids containing fluorine-based compounds such as C₃HCl₂F₅, C₄F₉OCH₃, C₄F₉OC₂H₅ or C₅H₃F₇ as the main component, and the boiling point is preferably 70° to 180° C. and more preferably 80° to 160° C. A fluorine-based inert liquid having a boiling point in the above-described range is advantageous in that the medium used in the liquid immersion can be removed by a simple method after the light exposure.

The fluorine-based inert liquid is particularly preferably a perfluoroalkyl compound in which all of the hydrogen atoms of the alkyl group are substituted with fluorine atoms. Examples of the perfluoroalkyl compounds include a perfluoroalkyl ether compound and a perfluoroalkylamine compound.

An specific example of the perfluoroalkyl ether compound includes perfluoro(2-butyl-tetrahydrofuran) (boiling point: 102° C.), and an example of the perfluoroalkylamine compound includes perfluorotributylamine (boiling point: 174° C.).

As the liquid immersion medium, water is preferable in terms of cost, safety, environment, and versatility.

An example of the alkali developing solution used for a developing treatment in an alkali developing process includes a 0.1 to 10% by mass aqueous solution of tetramethylammonium hydroxide (TMAH).

The organic solvent contained in the organic developing solution used for a developing treatment in a solvent developing process may be a solvent that is capable of dissolving the component (A) (prior to exposure) and can be properly selected from the conventionally known organic solvents. Specific examples of the organic solvent include polar solvents such as a ketone-based solvent, an ester-based solvent, an alcohol-based solvent, a nitrile-based solvent, an amide-based solvent, and an ether-based solvent, and a hydrocarbon-based solvent.

A ketone-based solvent is an organic solvent containing C—C(═O)—C in the structure thereof. An ester-based solvent is an organic solvent containing C—C(═O)—O—C in the structure thereof. An alcohol-based solvent is an organic solvent containing an alcoholic hydroxy group in the structure thereof. An “alcoholic hydroxy group” indicates a hydroxy group bonded to a carbon atom of an aliphatic hydrocarbon group. A nitrile-based solvent is an organic solvent containing a nitrile group in the structure thereof. An amide-based solvent is an organic solvent containing an amide group in the structure thereof. An ether-based solvent is an organic solvent containing C—O—C in the structure thereof.

Some organic solvents have a plurality of functional groups that characterizes the above-described solvent in the structure thereof. In such a case, the organic solvent corresponds to any type of solvents having the characteristic functional groups. For example, diethylene glycol monomethyl ether corresponds to an alcohol-based solvent or an ether-based solvent.

A hydrocarbon-based solvent consists of a hydrocarbon which may be halogenated and does not have any substituent other than a halogen atom. The halogen atom is preferably a fluorine atom.

Among the above, the organic solvent contained in the organic developing solution is preferably a polar solvent, and more preferably a ketone-based solvent, an ester-based solvent, and a nitrile-based solvent.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonylalcohol, acetylcarbinol, acetophenone, methyl naphthyl ketone, isophorone, propylenecarbonate, γ-butyrolactone and methyl amyl ketone (2-heptanone). Among these, methyl amyl ketone (2-heptanone) is preferable as a ketone-based solvent.

Examples of ester-based solvent include methyl acetate, butyl acetate, ethyl acetate, isopropyl acetate, amyl acetate, isoamyl acetate, ethyl methoxyacetate, ethyl ethoxyacetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these, the ester-based solvent is preferably butyl acetate.

Examples of nitrile-based solvent include acetonitrile, propionitrile, valeronitrile, and butyronitrile.

As necessary, the organic developing solution may be blended with a conventionally known additive. Examples of the additive include surfactants. The surfactant is not particularly limited, and for example, an ionic or non-ionic fluorine and/or a silicone-based surfactant can be used. The surfactant is preferably a non-ionic surfactant and more preferably a non-ionic fluorine surfactant or a non-ionic silicone-based surfactant.

In a case where a surfactant is blended, the amount of the surfactant to be blended is typically 0.001% to 5% by mass, preferably 0.005% to 2% by mass, and more preferably 0.01% to 0.5% by mass with respect to the total amount of the organic developing solution.

The developing treatment can be performed by a conventionally known developing method. Examples thereof include a method (a dip method) in which the support is dipped in a developing solution for a predetermined time, a method (a puddle method) in which a developing solution is cast onto the surface of the support by surface tension and maintained for a predetermined period, a method (a spray method) in which a developing solution is sprayed onto the surface of the support, and a method (a dynamic dispense method) in which a developing solution is continuously ejected and applied onto the support which rotates at a constant speed while the support is scanned with a developing solution ejecting and applying nozzle at a constant speed.

As the organic solvent contained in the rinse liquid that is used in the rinsing treatment after the developing treatment in a case of a solvent developing process, an organic solvent hardly dissolving the resist pattern can be properly selected and used, among the organic solvents mentioned as inorganic solvents that are used for the organic developing solution. In general, at least one kind of solvent selected from the group consisting of a hydrocarbon-based solvent, a ketone-based solvent, an ester-based solvent, an alcohol-based solvent, an amide-based solvent, and an ether-based solvent is used. Among these, at least one kind of solvent selected from the group consisting of a hydrocarbon-based solvent, a ketone-based solvent, an ester-based solvent, an alcohol-based solvent, and an amide-based solvent is preferable, at least one kind of solvent selected from the group consisting of an alcohol-based solvent and an ester-based solvent is more preferable, and an alcohol-based solvent is particularly preferable.

The alcohol-based solvent used for the rinse liquid is preferably a monohydric alcohol having 6 to 8 carbon atoms, and the monohydric alcohol may be linear, branched, or cyclic. Specific examples thereof include 1-hexanol, 1-heptanol, 1-octanol, 2-hexanol, 2-heptanol, 2-octanol, 3-hexanol, 3-heptanol, 3-octanol, 4-octanol, and benzyl alcohol. Among these, 1-hexanol, 2-heptanol, and 2-hexanol are preferable, and 1-hexanol and 2-hexanol are more preferable.

As the organic solvent, one kind of solvent may be used alone, or two or more kinds of solvents may be used in combination. Further, an organic solvent other than the above or water may be mixed for use. However, in consideration of the development characteristics, the amount of water to be blended in the rinse liquid is preferably 30% by mass or less, more preferably 10% by mass or less, still more preferably 5% by mass or less, and most preferably 3% by mass or less, with respect to the total amount of the rinse liquid.

A conventionally known additive can be blended with the rinse liquid as necessary. Examples of the additive include surfactants. Examples of the surfactant include the same surfactants as those described above, a non-ionic surfactant is preferable, and a non-ionic fluorine surfactant or a non-ionic silicone-based surfactant is more preferable.

In a case where a surfactant is blended, the amount of the surfactant to be blended is typically 0.001% to 5% by mass, preferably 0.005% to 2% by mass, and more preferably 0.01% to 0.5% by mass, with respect to the total amount of the rinse liquid.

The rinsing treatment (washing treatment) using a rinse liquid can be performed by a conventionally known rinse method. Examples of the rinsing treatment method include a method in which the rinse liquid is continuously ejected and applied onto a support which rotates at a constant rate (a rotational coating method), a method in which a support is dipped in the rinse liquid for a predetermined time (a dip method), and a method in which the rinse liquid is sprayed onto the surface of a support (a spray method).

According to the method of forming a resist pattern of the present embodiment described above, since the resist composition according to the first aspect described above is used, CDU and etching resistance are excellent.

### EXAMPLES

Hereinafter, the present invention will be described in more detail based on Examples, but the present invention is not limited to these Examples.

### EXAMPLES

### Synthesis Example 1

### Synthesis of Polymer Compound (A-1)

36.2 g of a monomer (a01-1-1), 25.0 g of a monomer (a02-1-1), and 4.6 g of azobis (isobutyric acid) dimethyl (V-601) as a polymerization initiator was dissolved in 217.0 g of methyl ethyl ketone (MEK), heated at 85° C. in a nitrogen atmosphere, and stirred for 5 hours. Thereafter, the obtained reaction solution was precipitated in 1,110 g of heptane and washed. The obtained white solid was filtered and dried under reduced pressure overnight to obtain 25.0 g of a target polymer compound (A-1).

[chemical structure]

The obtained polymer compound (A-1) had the standard polystyrene-equivalent weight-average molecular weight (Mw) of 12,800, which was determined by GPC measurement, and the polydispersity (Mw/Mn) of 1.68. The copolymerization compositional ratio (the ratio (molar ratio) between constitutional units in the structural formula) determined by ¹³C-NMR was 1/m=60/40.

### Synthesis Examples 2 to 13

In the same manner, polymer compounds (A-2) to (A-13) having the compositional ratios shown in Table 1 were synthesized using compounds shown below.

With respect to the obtained polymer compounds, the copolymerization compositional ratio (ratio between constitutional units in the polymer compound (molar ratio)) of the polymer compound, which was determined by ¹³C-NMR, the standard polystyrene-equivalent weight-average molecular weight (Mw), which was determined by GPC measurement, and the polydispersity (Mw/Mn) are shown in Table 1.

[chemical structure]

The polymer compound (A-1) to the polymer compound (A-13) respectively obtained by the Synthesis Examples described above are shown below.

[chemical structure]

TABLE 1

| | | | | Weight- | Poly- |
|---|---|---|---|---|---|
| | Poly- | Copolymerization | | average | dis- |
| | mer | compositional ratio | | molecular | persity |
| | com- | (molar ratio) of | | weight | (Mw/ |
| | pound | polymer compound | | (Mw) | Mn) |
| Synthesis | (A-1) | (a01-1-1)/(a02-1-1) = | 60/40 | 12,800 | 1.68 |
| Example 1 | | | | | |
| Synthesis | (A-2) | (a01-1-1)/(a02-1-1) = | 70/30 | 12,600 | 1.73 |
| Example 2 | | | | | |
| Synthesis | (A-3) | (a01-1-2)/(a02-1-1) = | 60/40 | 9,400 | 1.53 |
| Example 3 | | | | | |
| Synthesis | (A-4) | (a01-1-2)/(a02-1-1) = | 55/45 | 9,400 | 1.59 |
| Example 4 | | | | | |
| Synthesis | (A-5) | (a01-1-1)/(a02-1-1) = | 55/45 | 8,800 | 1.57 |
| Example 5 | | | | | |
| Synthesis | (A-6) | (a01-1-2)/(a02-1-1) = | 50/50 | 6,800 | 1.57 |
| Example 6 | | | | | |
| Synthesis | (A-7) | (a01-1-2)/(a02-1-1) = | 50/50 | 9,800 | 1.60 |
| Example 7 | | | | | |
| Synthesis | (A-8) | (a01-1-1)/(a02-1-1) = | 50/50 | 9,200 | 1.61 |
| Example 8 | | | | | |
| Synthesis | (A-9) | (a01-1-2)/(a2-1) = | 50/50 | 9,600 | 1.56 |
| Example 9 | | | | | |
| Synthesis | (A-10) | (a01-1-1)/(a2-2) = | 60/40 | 11,800 | 1.83 |
| Example 10 | | | | | |
| Synthesis | (A-11) | (a01-1-1)/(a2-1) = | 70/30 | 10,800 | 1.75 |
| Example 11 | | | | | |
| Synthesis | (A-12) | (a01-1-1)/(a2-1) = | 60/40 | 12,800 | 1.68 |
| Example 12 | | | | | |
| Synthesis | (A-13) | (a01-1-1)/(a2-1) = | 60/40 | 9,400 | 1.53 |
| Example 13 | | | | | |

<Preparation of Resist Composition>

### Examples 1 to 10 and Comparative Examples 1 to 8

Each of the components shown in Tables 2 and 3 was mixed and dissolved to prepare a resist composition of each Example.

TABLE 2

| | Component | Component | Component | Component | | |
|---|---|---|---|---|---|---|
| | (A) | (B) | (D) | (F) | Component(S) | |
| Example 1 | (A)-1 | (B1)-1 | (D)-1 | (F)-1 | (S1)-1 | (S2)-1 |
| | [100] | [6] | [12] | [2] | [50] | [2,600] |
| Example 2 | (A)-2 | (B1)-1 | (D)-1 | (F)-1 | (S1)-1 | (S2)-1 |
| | [100] | [6] | [12] | [2] | [50] | [2,600] |
| Example 3 | (A)-3 | (B1)-2 | (D)-1 | (F)-1 | (S1)-1 | (S2)-1 |
| | [100] | [10] | [12] | [2] | [50] | [2,600] |
| Example 4 | (A)-3 | (B1)-1 | (D)-1 | (F)-1 | (S1)-1 | (S2)-1 |
| | [100] | [4] | [12] | [2] | [50] | [2,600] |
| Example 5 | (A)-1 | (B1)-1 | (D)-1 | (F)-1 | (S1)-1 | (S2)-1 |
| | [100] | [4] | [12] | [2] | [50] | [2,600] |
| Example 6 | (A)-2 | (B1)-1 | (D)-1 | (F)-1 | (S1)-1 | (S2)-1 |
| | [100] | [4] | [12] | [2] | [50] | [2,600] |
| Example 7 | (A)-3 | (B1)-1 | (D)-1 | (F)-1 | (S1)-1 | (S2)-1 |
| | [100] | [6] | [12] | [2] | [50] | [2,600] |
| Example 8 | (A)-4 | (B1)-2 | (D)-1 | (F)-1 | (S1)-1 | (S2)-1 |
| | [100] | [10] | [12] | [2] | [50] | [2,600] |
| Example 9 | (A)-5 | (B1)-2 | (D)-1 | (F)-1 | (S1)-1 | (S2)-1 |
| | [100] | [10] | [12] | [2] | [50] | [2,600] |
| Example 10 | (A)-1 | (B1)-1 | (D)-1 | (F)-1 | — | (S2)-1 |
| | [100] | [6] | [12] | [2] | | [2,600] |

TABLE 3

| | Component | Component | Component | Component | | |
|---|---|---|---|---|---|---|
| | (A) | (B) | (D) | (F) | Component(S) | |
| Comparative | (A)-6 | (B1)-1 | (D)-1 | (F)-1 | (S1)-1 | (S2)-1 |
| Example 1 | [100] | [6] | [12] | [2] | [50] | [2,600] |
| Comparative | (A)-7 | (B1)-2 | (D)-1 | (F)-1 | (S1)-1 | (S2)-1 |
| Example 2 | [100] | [10] | [12] | [2] | [50] | [2,600] |
| Comparative | (A)-8 | (B1)-2 | (D)-1 | (F)-1 | (S1)-1 | (S2)-1 |
| Example 3 | [100] | [10] | [12] | [2] | [50] | [2,600] |
| Comparative | (A)-9 | (B1)-2 | (D)-1 | (F)-1 | (S1)-1 | (S2)-1 |
| Example 4 | [100] | [10] | [12] | [2] | [50] | [2,600] |
| Comparative | (A)-10 | (B1)-2 | (D)-1 | (F)-1 | (S1)-1 | (S2)-1 |
| Example 5 | [100] | [10] | [12] | [2] | [50] | [2,600] |
| Comparative | (A)-11 | (B1)-2 | (D)-1 | (F)-1 | (S1)-1 | (S2)-1 |
| Example 6 | [100] | [10] | [12] | [2] | [50] | [2,600] |
| Comparative | (A)-12 | (B1)-1 | (D)-2 | (F)-1 | (S1)-1 | (S2)-1 |
| Example 7 | [100] | [6] | [12] | [2] | [50] | [2,600] |
| Comparative | (A)-13 | (B1)-2 | (D)-1 | (F)-1 | (S1)-1 | (S2)-1 |
| Example 8 | [100] | [10] | [12] | [2] | [50] | [2,600] |

In Tables 2 and 3, each abbreviation has the following meaning. The numerical value in the bracket indicates the blending amount (parts by mass).

(A)-1 to (A)-13: the polymer compounds (A-1) to (A-13).

(B1)-1: an acid generator composed of a compound represented by Chemical Formula (B1-1).

(B1)-2: an acid generator composed of a compound represented by Chemical Formula (B1-2).

[chemical structure]

(D)-1: an acid diffusion controlling agent composed of a compound represented by Chemical Formula (D-1).

[chemical structure]

(F)-1: a fluorine-containing polymer compound represented by Chemical Formula (F-1). The standard polystyrene-equivalent mass-average molecular weight (Mw) determined by GPC measurement and the polydispersity (Mw/Mn) are respectively 36,900 and 1.82.

[chemical structure]

(S1)-1: Propylene Carbonate

(S2)-1: a mixed solvent of propylene glycol monomethyl ether acetate propylene glycol monomethyl ether/cyclohexanone=45/25/30 (mass ratio)

<Formation of Resist Pattern>

An organic antireflection film composition “ARC95” (trade name, manufactured by Brewer Science Inc.) was applied onto a 12-inch silicon wafer using a spinner to form an organic antireflection film having a film thickness of 89 nm.

Next, the resist composition of each Example was applied onto the organic antireflection film using a spinner, the coated wafer was subjected to a post-apply baking (PAB) treatment on a hot plate at a temperature of 110° C. for 60 seconds so that the coated wafer was dried to form a resist film having a film thickness of 110 nm.

Next, the resist film was selectively irradiated with an ArF excimer laser (193 nm) over a phase shift mask (6% transmission) using a liquid immersion ArF lithography apparatus NSR—S609B [manufactured by Nikon Corporation; numerical aperture (NA)=1.05, Annular (0.87/0.68) with Y-Polarization, liquid immersion medium: water].

Thereafter, a post-exposure baking (PEB) treatment was performed at 110° C. for 60 seconds.

Subsequently, solvent developing was carried out with butyl acetate at 23° C. for 30 seconds, and shake-off drying was performed.

As a result, in all Examples, a contact hole pattern (hereinafter, referred to as “CH pattern”) in which holes having a diameter of 80 nm were arranged at equal intervals (pitch: 150 nm) was formed.

[Evaluation of in-Plane Uniformity (CDU) of Pattern Dimensions]

400 holes in the CH pattern formed according to <Formation of resist pattern> described above were observed above the CH pattern by a critical dimension-scanning electron microscope (CD-SEM, accelerating voltage: 500V, trade name: CG5000, manufactured by Hitachi High-Tech Corporation) and the hole diameter (nm) of each hole was measured. Then, a triple value (3σ) of the standard deviation (σ) calculated from the measurement result was obtained. The results are shown in Tables 4 and 5 as “CDU (nm)”.

The smaller the value of 3σ obtained in this manner is, the higher the critical dimension (CD) uniformity of the plurality of holes formed in the resist film is.

[Evaluation of Etching Resistance]

With respect to the large area unexposed portion (resist film) located next to the CH pattern area formed according to <Formation of resist pattern> described above, dry etching (CF plasma etching) was performed under the conditions described below with plasma obtained from fluorocarbon gas to measure etching speed of the large area exposed portion, and the etch rate (the thickness of the film of the large area exposed portion etched per unit time)) was determined from the difference between the film thicknesses of the large area exposed portion before and after etching. Etching resistance was evaluated based on the etch rate according to the following criteria. The results are shown in Tables 4 and 5.

[CF Plasma Etching]

Apparatus: a high vacuum RIE apparatus (manufactured by Tokyo Ohka Kogyo Co., Ltd.; product name “TCE-3822”)

Gas: CF₄, N₂

Output: 400 W

Chamber pressure: 40 Pa

Stage temperature: 40° C.

Gas flow rate: 20 mL/min

[Evaluation Criteria]

A: 50% or more of the large area exposed portion (resist film) remains after 60 s etching.

B: 30% or more and less than 50% of the large area exposed portion (resist film) remains after 60 s etching.

C: less than 30% of the large area exposed portion (resist film) remains after 60 s etching.

[Evaluation of Residue]

With respect to the large area unexposed portion next to the CH pattern area formed according to <Formation of resist pattern> described above, the presence or absence of residues in the large area unexposed portion was checked by a critical dimension-scanning electron microscope (CD-SEM, accelerating voltage: 500V, trade name: CG5000, manufactured by Hitachi High-Tech Corporation). The results are shown in Tables 4 and 5.

TABLE 4

| | PAB | PEB | CDU | Etching | |
|---|---|---|---|---|---|
| | (° C.) | (° C.) | [nm] | resistance | Residue |
| Example 1 | 110 | 110 | 3.8 | A | Absent |
| Example 2 | 110 | 110 | 4.0 | A | Absent |
| Example 3 | 110 | 110 | 3.4 | A | Absent |
| Example 4 | 110 | 110 | 4.1 | A | Absent |
| Example 5 | 110 | 110 | 3.9 | A | Absent |
| Example 6 | 110 | 110 | 4.0 | A | Absent |
| Example 7 | 110 | 110 | 3.7 | A | Absent |
| Example 8 | 110 | 110 | 4.2 | A | Absent |
| Example 9 | 110 | 110 | 4.1 | A | Absent |
| Example 10 | 110 | 110 | 4.3 | A | Present |

TABLE 5

| | PAB | PEB | CDU | Etching | |
|---|---|---|---|---|---|
| | (° C.) | (° C.) | [nm] | resistance | Residue |
| Comparative | 110 | 110 | 6.8 | A | Present |
| Example 1 | | | | | |
| Comparative | 110 | 110 | 6.3 | A | Present |
| Example 2 | | | | | |
| Comparative | 110 | 110 | 5.9 | A | Present |
| Example 3 | | | | | |
| Comparative | 110 | 110 | 6.5 | C | Present |
| Example 4 | | | | | |
| Comparative | 110 | 110 | 4.3 | B | Absent |
| Example 5 | | | | | |
| Comparative | 110 | 110 | 4.5 | C | Absent |
| Example 6 | | | | | |
| Comparative | 110 | 110 | 4.9 | C | Absent |
| Example 7 | | | | | |
| Comparative | 110 | 110 | 4.8 | C | Absent |
| Example 8 | | | | | |

From the results shown in Tables 4 and 5, it can be confirmed that the resist compositions of Examples can form a resist pattern excellent in CDU and etching resistance in forming the resist pattern, as compared with the resist compositions of Comparative Examples.

Further, it can be confirmed that the resist compositions of Examples 1 to 9 containing propylene carbonate suppress the generation of residues in addition to the above effects.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A resist composition which generates an acid upon exposure and exhibits changed solubility in a developing solution under action of acid, the resist composition comprising:
a resin component (A1) exhibiting changed solubility in a developing solution under action of acid,
wherein the resin component (A1) contains a polymer compound having a constitutional unit (a01) represented by General Formula (a01-1) and a constitutional unit (a02) represented by General Formula (a02-1), and
a proportion of the constitutional unit (a01) is more than 50% by mole and 70% by mole or less with respect to a total amount (100% by mole) of all constitutional units constituting the polymer compound: [chemical structure]
wherein, in Formula (a01-1), R represents a hydrogen atom, an alkyl group having 1 to 5 carbon atoms, or a halogenated alkyl group having 1 to 5 carbon atoms, Va⁰¹ represents a divalent hydrocarbon group which may have an ether bond, nₐ₀₁ represents an integer of 0 to 2, Ra⁰⁰ is an acid dissociable group represented by General Formula (a01-r-1); and
in Formula (a01-r-1), Ra⁰⁰¹ to Ra⁰⁰³ each independently represent a hydrocarbon group, and Ra⁰⁰² and Ra⁰⁰³ may be bonded with each independently other to form a ring, and * represents a bonding site; [chemical structure]
wherein, in Formula (a02-1), R represents a hydrogen atom, an alkyl group having 1 to 5 carbon atoms, or a halogenated alkyl group having 1 to 5 carbon atoms, Va⁰² represents a divalent hydrocarbon group which may have a substituent, nₐ₀₂ represents an integer of 0 to 2, Ra¹ and Ra² each independently represent a hydrogen atom, an alkyl group having 1 to 5 carbon atoms, an alkoxy group, or an alkylthio group, or Ra¹ and Ra² may be bonded to each other to form an alkylene group having 1 to 6 carbon atoms, which may contain an oxygen atom or sulfur atom, an ether bond, or a thioether bond, Ra′⁰¹ represents a halogen atom, an alkyl group having 1 to 6 carbon atoms, which may have a halogen atom, a hydroxyalkyl group having 1 to 6 carbon atoms, in which a hydroxy moiety may be protected by a protecting group and which may have a halogen atom, a carboxy group which may form a salt, or a substituted oxycarbonyl group, p₀ represents an integer of 0 to 8, in a case where two or more Ra′⁰¹'s are present, a plurality of Ra′⁰¹'s may be the same or different from each other, and q₀₁ represents an integer of 1 to 9.

2. The resist composition according to claim 1, further comprising a carbonate-based solvent (S1).

3. The resist composition according to claim 2, wherein the carbonate-based solvent (S1) is propylene carbonate.

4. The resist composition according to claim 1, wherein the constitutional unit (a02) is a constitutional unit represented by General Formula (a02-11): [chemical structure]
wherein R represents a hydrogen atom, an alkyl group having 1 to 5 carbon atoms, or a halogenated alkyl group having 1 to 5 carbon atoms, Va⁰² represents a divalent hydrocarbon group which may have a substituent, nₐ₀₂ represents an integer of 0 to 2, and q₀₂ represents an integer of 1 to 7.

5. The resist composition according to claim 3, wherein the constitutional unit (a02) is a constitutional unit represented by General Formula (a02-11), [chemical structure]
wherein, in Formula (a02-11), R represents a hydrogen atom, an alkyl group having 1 to 5 carbon atoms, or a halogenated alkyl group having 1 to 5 carbon atoms, Va⁰² represents a divalent hydrocarbon group which may have a substituent, nₐ₀₂ represents an integer of 0 to 2, and q₀₂ represents an integer of 1 to 7.

6. The resist composition according to claim 1, wherein in Formula (a01-1), Ra⁰⁰ represents an acid dissociable group represented by General Formula (a01-r-11), [chemical structure]
wherein, in Formula (a01-r-11), Ya¹¹ represents a carbon atom, Xa¹¹ represents a group that forms a monocyclic alicyclic hydrocarbon group together with Ya¹¹, a part or all of the hydrogen atoms that the monocyclic alicyclic hydrocarbon group has may be substituted, Ra¹¹ represents a hydrocarbon group which may have a substituent, and * represents a bonding site.

7. The resist composition according to claim 5, wherein in Formula (a01-1), Ra⁰⁰ represents an acid dissociable group represented by General Formula (a01-r-11), [chemical structure]
wherein, in Formula (a01-r-11), Ya¹¹ represents a carbon atom, Xa¹¹ represents a group that forms a monocyclic alicyclic hydrocarbon group together with Ya¹¹, a part or all of the hydrogen atoms that the monocyclic alicyclic hydrocarbon group has may be substituted, Ra¹¹ represents a hydrocarbon group which may have a substituent, and * represents a bonding site.

8. The resist composition according to claim 1, wherein a proportion of the constitutional unit (a02) is 30% by mole or more and less than 50% by mole with respect to a total amount (100% by mole) of all constitutional units constituting the polymer compound.

9. The resist composition according to claim 7, wherein a proportion of the constitutional unit (a02) is 30% by mole or more and less than 50% by mole with respect to a total amount (100% by mole) of all constitutional units constituting the polymer compound.

10. The resist composition according to claim 1, wherein the resin component (A1) consists of a repeated structure of the constitutional unit (a01) and the constitutional unit (a02).

11. The resist composition according to claim 7, wherein the resin component (A1) consists of a repeated structure of the constitutional unit (a01) and the constitutional unit (a02).

12. A method of forming a resist pattern, comprising:
forming a resist film on a support using the resist composition according to claim 1;
exposing the resist film; and
developing the exposed resist film to form a resist pattern.

13. The method of forming a resist pattern according to claim 12, wherein the exposed resist film is developed using a developing solution containing an organic solvent.
